(19) United States
(12) Patent Application Publication
(10) Pub. No.: US 2008/0048202 A1
(43) Pub. Date: Feb. 28, 2008

(54) SEMICONDUCTOR LIGHT EMITTING DEVICE, METHOD OF FORMING THE SAME, AND COMPOUND SEMICONDUCTOR DEVICE

(75) Inventors: Mikio Tazima, Tokyo (JP); Yoshiki Tada, Niiza-shi (JP); Yasuhiro Kamii, Otsu-shi (JP)

Correspondence Address: WOOD, HERRON & EVANS, LLP, 2700 CAREW TOWER, 441 VINE STREET, CINCINNATI, OH, 45202, US

(73) Assignee: SANKEN ELECTRIC CO., LTD., Saitama-ken (JP)

(21) Appl. No.: 11/782,247

(22) Filed: Jul. 24, 2007

(30) Foreign Application Priority Data
Aug. 25, 2006 (JP) 2006-229404

(51) Int. Cl. H01L 33/00

(52) U.S. Cl. 257/98; 438/29; 257/E33.068

(57) ABSTRACT

A semiconductor device may include, but is not limited to, a substrate, a compound semiconductor epitaxial layer, and a first reflecting layer. The substrate may have a main face. The substrate may have at least one cavity that is adjacent to the main face. The compound semiconductor epitaxial layer may have first and second faces adjacent to each other. The first face may contact with the main face. The second face may face toward the at least one cavity. The compound semiconductor epitaxial layer may include, but is not limited to, at least one light emitting layer that emits light. The first reflecting layer may be in the at least one cavity. The first reflecting layer may contact with the second face. The first reflecting layer may be higher in light-reflectivity than the substrate.

### BACKGROUND OF THE INVENTION

1. Field of the Invention

The present invention generally relates to a semiconductor light emitting device including a light emitting layer, a method of forming the semiconductor light emitting device, and a compound semiconductor device.

Priority is claimed on Japanese Patent Application No. 2006-229404, filed Aug. 25, 2006, the content of which is incorporated herein by reference.

2. Description of the Related Art

All patents, patent applications, patent publications, scientific articles, and the like, which will hereinafter be cited or identified in the present application, will hereby be incorporated by reference in their entirety in order to describe more fully the state of the art to which the present invention pertains.

Japanese Unexamined Patent Application, First Publication, No. 2003-243699 discloses a conventional semiconductor light emitting device. The conventional semiconductor light emitting device is fabricated by a set of processes that includes a process for combining substrates. The conventional semiconductor light emitting device includes a light emitting layer that emits lights toward opposite directions, namely upward and downward directions. The conventional semiconductor light emitting device also includes a reflecting layer that lies under the light emitting layer. The conductive reflecting layer is highly conductive.

The light emitting layer respectively emits first and second lights upwardly and downwardly. The first light travels downwardly and reaches the conductive reflecting layer. The first light is then reflected by the conductive reflecting layer. The reflected first light travels upwardly. The reflected first light is combined with the second light to generate a combined beam of light which travels upwardly. Reflecting the first light by the conductive reflecting layer increases the luminance of the combined beam of light that is output from the conventional semiconductor light emitting device.

The set of processes for fabricating the conventional semiconductor light emitting device includes the processes for preparing a light emitting layer and a conductive plate and combining the light emitting layer and the conductive plate. The light emitting layer has a multi-layered structure that includes a highly conductive reflecting layer. The highly conductive reflecting layer forms a surface of the light emitting layer. The conductive plate performs as a base for the semiconductor light emitting device. The conductive plate also performs as an electrode of the semiconductor light emitting device. The combining process is performed so that the highly conductive reflecting layer is made into contact tightly with the conductive plate.

The multi-layered structure of the light emitting layer is prepared by using epitaxial growth. In order to perform epitaxial growth, it is necessary to prepare another base of a substrate on which the multi-layered structure of the light emitting layer is epitaxially grown. The other base of a substrate for epitaxial growth is different from the conductive plate. Namely, the conductive plate can not be used as a base for epitaxial growth.

The above-described combining process needs additional processes. Namely, the other base for epitaxial growth is prepared. Then, the multi-layered structure of the light emitting layer is formed on the other base by epitaxial growth. After the epitaxial growth process has been completed, the other base is removed by an etching process. The above-described conventional method of forming the semiconductor device causes disadvantages of inevitably increasing the manufacturing cost.

It is actually difficult to obtain good adhesiveness between the highly conductive reflecting layer and the conductive plate as well as between the highly conductive reflecting layer and the light emitting layer. Thus, it is actually difficult to obtain high reflectivity of the semiconductor light emitting device.

In view of the above, it will be apparent to those skilled in the art from this disclosure that there exists a need for an improved apparatus and/or method. This invention addresses this need in the art as well as other needs, which will become apparent to those skilled in the art from this disclosure.

### SUMMARY OF THE INVENTION

Accordingly, it is a primary object of the present invention to provide a semiconductor light emitting device.

It is another object of the present invention to provide a semiconductor light emitting device which is free from the disadvantages described above.

It is a further object of the present invention to provide a high luminance semiconductor light emitting device.

It is a still further object of the present invention to provide a semiconductor light emitting device which can be fabricated easily.

It is yet a further object of the present invention to provide a method of forming a semiconductor light emitting device.

It is an additional object of the present invention to provide a method of forming a semiconductor light emitting device, which is free from the disadvantages described above.

It is another object of the present invention to provide a composite semiconductor light emitting device.

It is still another object of the present invention to provide a composite semiconductor light emitting device which is free from the disadvantages described above.

In accordance with a first aspect of the present invention, a semiconductor light emitting device may include, but is not limited to, a substrate, a light emitting layer, and a reflecting layer. The substrate may have a main face and a cavity that is adjacent to the main face. The light emitting layer may extend over the main face and the cavity. The light emitting layer may have a first portion that faces to the cavity. The light emitting layer may have a light emitting function. The reflecting layer may fill the cavity. The reflecting layer may be higher in light-reflectivity than the substrate. The reflecting layer may contact with the first portion of the light emitting layer. The reflecting layer may have the edge that is in plan view aligned to or positioned inside the edge of the light emitting layer.

In some cases, the reflecting layer may include, but is not limited to, a first reflecting layer; and a second reflecting layer being in the first reflecting layer. The second reflecting layer may be different in refractive index from the first reflecting layer.

In accordance with a second aspect of the present invention, a semiconductor light emitting device may include, but is not limited to, a substrate, a light emitting layer, and a reflecting layer. The substrate may have a main face and a cavity that is adjacent to the main face. The light emitting layer may have first and second portions, wherein the first portion contacts with the main face, and the second portion faces to the cavity. The light emitting layer may have a light emitting function. The reflecting layer may be on the second portion. The reflecting layer may be higher in light-reflectivity than the substrate. The reflecting layer may have an irregular interface with the first portion of the light emitting layer.

In some cases, the reflecting layer may have at least a portion of the edge. The portion may be in plan view positioned outside the edge of the light emitting layer.

In accordance with a third aspect of the present invention, a semiconductor light emitting device may include, but is not limited to, a substrate, a light emitting layer, and a reflecting layer. The substrate may have a main face and a cavity that is adjacent to the main face. The light emitting layer may extend over the main face and the cavity. The light emitting layer may have a first portion that faces to the cavity. The light emitting layer may have a light emitting function. The reflecting layer may be in the cavity. The reflecting layer contacts with the first portion. The reflecting layer may be higher in light-reflectivity than the substrate. At least a part of the wall of the cavity may be separated from the reflecting layer.

In some cases, the reflecting layer may have at least a portion of the edge. The portion may be in plan view positioned outside the edge of the light emitting layer.

In some cases, the reflecting layer may include, but is not limited to, a first reflecting layer; and a second reflecting layer being in the first reflecting layer. The second reflecting layer may be different in refractive index from the first reflecting layer.

In accordance with a fourth aspect of the present invention, a composite semiconductor device may include, but is not limited to, a substrate, a light emitting layer, a reflecting layer, a first electrode, a second electrode, and a protective device. The substrate may have a main face and a cavity that is adjacent to the main face. The light emitting layer may extend over the main face and the cavity. The light emitting layer may have a first portion that faces to the cavity. The light emitting layer may have a light emitting function. The reflecting layer may fill the cavity. The reflecting layer may be higher in light-reflectivity than the substrate. The reflecting layer may contact with the first portion of the light emitting layer. The first electrode may have first and second parts. The first part may be on the light emitting layer. The second part may be connected to the first part. The second part may perform as a pad electrode. The second electrode may be on an opposing face of the substrate to the main face. The protective device may be placed between the second part and the opposing face. The protective device may be eclectically connected to the first and second electrodes. The reflecting layer may have at least a side portion that is positioned in plan view outside the edge of the light emitting layer.

In accordance with a fifth aspect of the present invention, a method of forming a semiconductor light emitting device may include, but is not limited to, the following processes. A light emitting layer is formed on a main face of a substrate. The light emitting layer has a light emitting function. At least one through-hole is formed in the compound semiconductor epitaxial layer. At least one cavity is formed in the substrate. The at least one cavity is adjacent to the main face. The at least one cavity is present under the at least one through-hole and a first portion of the light emitting layer. The first portion has a first face that faces toward the at least one cavity. At least one first reflecting layer is formed, which fills the at least one cavity The first reflecting layer is higher in light-reflectivity than the substrate. Side edges of the substrate and the at least one first reflecting layer are removed.

In accordance with a sixth aspect of the present invention, a method of forming a semiconductor light emitting device may include, but is not limited to, the following processes. A light emitting layer is formed on a main face of a substrate. The light emitting layer has a light emitting function. At least one through-hole is formed in the compound semiconductor epitaxial layer. At least one cavity is formed in the substrate. The at least one cavity is adjacent to the main face. The at least one cavity is present under the at least one through-hole and a first portion of the light emitting layer. The first portion has a first face that faces toward the at least one cavity. The first face is made into an irregular face. At least one first reflecting layer is deposited on the irregular face. The first reflecting layer is higher in light-reflectivity than the substrate.

In accordance with a seventh aspect of the present invention, a method of forming a semiconductor light emitting device may include, but is not limited to, the following processes. A light emitting layer is formed on a main face of a substrate. The light emitting layer has a light emitting function. At least one through-hole is formed in the compound semiconductor epitaxial layer. At least one cavity is formed in the substrate. The at least one cavity is adjacent to the main face. The at least one cavity is present under the at least one through-hole and a first portion of the light emitting layer. The first portion has a first face that faces toward the at least one cavity. At least one first reflecting layer is deposited on the first face. The first reflecting layer is higher in light-reflectivity than the substrate.

In accordance with an eighth aspect of the present invention, a semiconductor device may include, but is not limited to, a substrate, a compound semiconductor epitaxial layer, and a first reflecting layer. The substrate may have a main face. The substrate may have at least one cavity that is adjacent to the main face. The compound semiconductor epitaxial layer may have first and second faces adjacent to each other. The first face may contact with the main face. The second face may face toward the at least one cavity. The compound semiconductor epitaxial layer may include, but is not limited to, at least one light emitting layer that emits light. The first reflecting layer may be in the at least one cavity. The first reflecting layer may contact with the second face. The first reflecting layer may be higher in light-reflectivity than the substrate.

In some cases, the first reflecting layer may at least partially contact with the wall of the at least one cavity.

In some cases, the first reflecting layer may have an irregular interface with the second face.

In some cases, the semiconductor device may further include, but is not limited to, a second reflecting layer. The second reflecting layer may contact with the first reflecting layer. The second reflecting layer may be separated by the first reflecting layer from the second face. The second reflecting layer may be different in refractive index from the first reflecting layer.

In some cases, the semiconductor device may further include, but is not limited to, a first electrode, a second electrode and a protective device. The first electrode may have first and second parts. The first part may contact with the compound semiconductor epitaxial layer. The second part may contact with the first part. The second electrode may contact with the substrate. The protective device may be electrically connected to the second part and the second electrode.

In some cases, the reflecting layer may have the edge, at least a part of which is positioned in plan view outside the edge of the compound semiconductor epitaxial layer.

In some cases, the compound semiconductor epitaxial layer may further include a compound semiconductor buffer layer that contacts with the main face and the reflecting layer.

In accordance with a ninth aspect of the present invention, a method of forming a semiconductor device may include, but is not limited to, the following processes. A compound semiconductor epitaxial layer is formed on a main face of a substrate. The compound semiconductor epitaxial layer includes at least one light emitting layer that emits light. At least one through-hole sis formed in the compound semiconductor epitaxial layer. The at least one-through hole is adjacent to a first portion of the compound semiconductor epitaxial layer. At least one cavity is formed in the substrate. The at least one cavity is adjacent to the main face. The at least one cavity is present under the first portion and the at least one through-hole. The first portion has a first face that faces toward the at least one cavity. At least one first reflecting layer is formed in the at least one cavity. The at least one first reflecting layer contacts with the first face. The first reflecting layer is higher in light-reflectivity than the substrate.

In some cases, the method may further include, but is not limited tom the following process. The first face is made into an irregular face before forming at least one first reflecting layer so that the at least one first reflecting layer contacts with the irregular face.

In some cases, the at least one first reflecting layer may be formed by completely filling the at least one cavity with the at least one first reflecting layer.

In some cases, the at least one first reflecting layer may be formed by depositing the at least one first reflecting layer on the first face so that the at least one first reflecting layer is film-shaped and partially fills the at least one cavity.

In some cases, the at least one first reflecting layer may be formed by partially filling the at least one first reflecting layer in the at least one cavity so that the at least one first reflecting layer has an additional cavity. The method may further include, but is not limited to the following process. A second reflecting layer is formed in the additional cavity. The second reflecting layer is separated by the at least one first reflecting layer from the second face. The second reflecting layer is different in refractive index from the at least one first reflecting layer.

These and other objects, features, aspects, and advantages of the present invention will become apparent to those skilled in the art from the following detailed descriptions taken in conjunction with the accompanying drawings, illustrating the embodiments of the present invention.

### BRIEF DESCRIPTION OF THE DRAWINGS

Referring now to the attached drawings which form a part of this original disclosure:

FIG. 1 is a fragmentary cross sectional elevation view illustrating a semiconductor light emitting device in accordance with a first embodiment of the present invention;

FIG. 2 is a plan view illustrating a semiconductor light emitting device of FIG. 1 which illustrates, taken along a I-I line;

FIG. 3 is a plan view illustrating a modified example of the semiconductor light emitting device of FIG. 1;

FIG. 4 is a fragmentary cross sectional elevation view illustrating a modified example of the semiconductor light emitting device in accordance with a first embodiment of the present invention;

FIGS. 5A through 5H are fragmentary cross sectional elevation views illustrating semiconductor light emitting devices in sequential steps involved in a method of forming the semiconductor light emitting device in accordance with the first embodiment of the present invention;

FIG. 6 is a fragmentary cross sectional elevation view illustrating a modified semiconductor light emitting device in accordance with the first embodiment of the present invention;

FIG. 7 is a fragmentary cross sectional elevation view illustrating a semiconductor light emitting device in accordance with a second embodiment of the present invention;

FIGS. 8A through 8D are fragmentary cross sectional elevation views illustrating semiconductor light emitting devices in sequential steps involved in a method of forming the semiconductor light emitting device in accordance with the second embodiment of the present invention;

FIG. 9 is a fragmentary cross sectional elevation view illustrating a modified semiconductor light emitting device in accordance with the second embodiment of the present invention;

FIG. 10 is a fragmentary cross sectional elevation view illustrating another modified semiconductor light emitting device in accordance with the second embodiment of the present invention;

FIG. 11 is a plan view illustrating the other modified semiconductor light emitting device of FIG. 10, which illustrates it taken along a II-II line of FIG. 11;

FIG. 12 is a fragmentary cross sectional elevation view illustrating a semiconductor light emitting device in accordance with a third embodiment of the present invention;

FIG. 13 is a fragmentary cross sectional elevation view illustrating a cavity of a conductive substrate before the dicing process involved in the method of forming the light emitting device of FIG. 12;

FIGS. 14A through 14C are fragmentary cross sectional elevation views illustrating semiconductor light emitting devices in sequential steps involved in a method of forming the semiconductor light emitting device in accordance with the third embodiment of the present invention;

FIG. 15 is a fragmentary cross sectional elevation view illustrating a composite semiconductor device in accordance with a fourth embodiment of the present invention;

FIG. 16 is a circuit diagram illustrating an equivalent circuit of the composite semiconductor device of FIG. 15;

FIG. 17 is a fragmentary cross sectional elevation view illustrating a first modified composite semiconductor device in accordance with a first modification of the fourth embodiment of the present invention;

FIG. 18 is a fragmentary cross sectional elevation view illustrating a second modified composite semiconductor device in accordance with a second modification of the fourth embodiment of the present invention;

FIG. 19 is a plan view illustrating a first example of the two-dimensional periodical array structure of the second modified composite semiconductor device of FIG. 18; and

FIG. 20 is a plan view illustrating a second example of the two-dimensional periodical array structure of the second modified composite semiconductor device of FIG. 18.

### DETAILED DESCRIPTION OF THE INVENTION

Selected embodiments of the present invention will now be described with reference to the drawings. It will be apparent to those skilled in the art from this disclosure that the following descriptions of the embodiments of the present invention are provided for illustration only and not for the purpose of limiting the invention as defined by the appended claims and their equivalents.

### First Embodiment

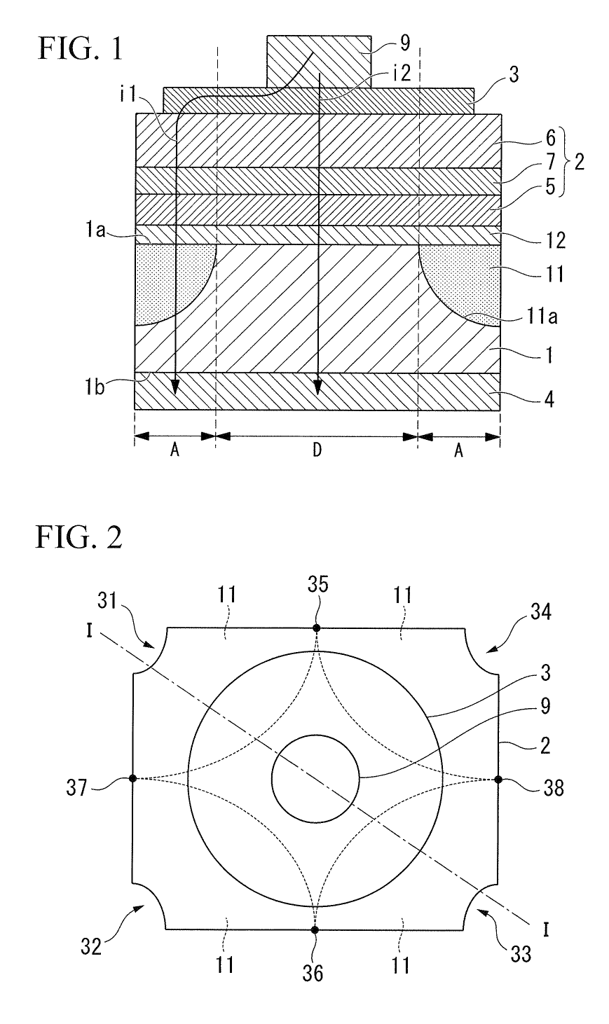

A first embodiment of the present invention will be described. FIG. 1 is a fragmentary cross sectional elevation view illustrating a semiconductor light emitting device in accordance with a first embodiment of the present invention. FIG. 2 is a plan view illustrating a semiconductor light emitting device of FIG. 1 which illustrates, taken along a I-I line.

As shown in FIG. 1, the semiconductor light emitting device includes a conductive substrate 1, a light emitting layer 2, first and second electrodes 3 and 4, a pad electrode 9, reflecting layers 11, and a buffer layer 12. The stacked structure of the light emitting layer 2 and the buffer layer 12 forms a compound semiconductor epitaxial layer. In other words, the semiconductor light emitting device includes a compound semiconductor epitaxial layer that includes the light emitting layer 2 and the buffer layer 12.

The conductive substrate 1 is electrically conductive. The conductive substrate 1 has first and second main faces 1a and 1b. The conductive substrate 1 also has cavities 11a which are adjacent to the first main face 1a. The light emitting layer 2 emits beams of light in opposite directions which are vertical to the surfaces of the light emitting layer 2. The light emitting layer 2 emits beams of light, for example, in upward and downward directions. The light emitting layer 2 may have a multi-layered structure which, for example, includes a first cladding layer 5, a second cladding layer 6, and an activation layer 7. Further, the semiconductor light emitting device includes a passivation layer that is not illustrated.

The second electrode 4 is disposed adjacent to the second main face 11b of the conductive substrate 1. The conductive reflecting layers 11 are disposed in the cavities 11a of the conductive substrate 1. The conductive reflecting layers 11 have surfaces that are leveled to the first main face 1a of the conductive substrate 1. The buffer layer 12 is disposed adjacent to the first main face of the substrate 1 and to the conductive reflecting layers 11. The light emitting layer 2 is disposed adjacent to the buffer layer 12 so that the buffer layer 12 is interposed between the light emitting layer 2 and the conductive substrate 1. As described above, the light emitting layer 2 includes the first and second cladding layers 5 and 6, and the activation layer 7. The first cladding layer 5 is adjacent to the buffer layer 12. The activation layer 7 is adjacent to the first cladding layer 5. The second cladding layer 6 is adjacent to the activation layer 7. The activation layer 7 is interposed between the first and second cladding layers 5 and 6.

The first electrode 3 is disposed adjacent to the second cladding layer 6 so that the second cladding layer 6 is interposed between the first electrode 3 and the activation layer 7. The pad electrode 9 is disposed on the first electrode 3.

The conductive substrate 1 is electrically conductive. Atypical example of the conductive substrate 1 may include, but is not limited to, a silicon-based substrate made of silicon or silicon carbide. The conductive substrate 1 performs as a base for epitaxial growth of the buffer layer 12 and the light emitting layer 2. The conductive substrate 1 also provides a current path for the semiconductor light emitting device. The conductive substrate 1 performs as a supporter that supports the light emitting layer 2 and the first electrode 3.

The silicon-based semiconductor used for the conductive substrate 1 may have a high concentration of an impurity so that the conductive substrate 1 has a reduced resistivity. Namely, the conductive substrate 1 may be made of a highly-doped silicon based semiconductor. In some cases, the silicon-based semiconductor may contain the Group III element such as boron as a p-type impurity. The silicon-based semiconductor may, for example, have a P-type impurity concentration in the range of 5E18-5E19 [cm⁻³]. The silicon-based semiconductor may, for example, have a resistivity in the range of 0.0001-0.01 [Ωcm]. In other cases, the silicon-based semiconductor may contain the Group V element such as phosphorus as an N-type impurity.

The conductive substrate 1 has the first and second main faces 1a and 1b. The first main face may be (111)-face in Miller indexes. The conductive substrate 1 has a thickness in the range of 200-700 micrometers.

The conductive substrate 1 has the cavities 11a which are adjacent to the first main face 1a. The cavities 11a have walls that are curved toward the inside of the conductive substrate 1. The cavities 11a are disposed outside the first main face 1a. In plan view, the cavities 11a extend in the areas A, while the first main face 1a extends in the area D. The cavities 11a may be formed in any available set of know processes. For example, the buffer layer 12 is formed on the first main face 1a of the conductive substrate 1. The light emitting layer 2 is then formed on the buffer layer 12. The light emitting layer 2 is selectively etched to form a through-hole therein so that parts of the first main face 1a of the conductive substrate 1 are shown through the through-hole. The shown parts of the first main face 1a are then subjected to an isotropic etching process, thereby forming the cavities 11a.

The conductive reflecting layers 11 are disposed in the cavities 11a. The conductive reflecting layers 11 may be formed by filling the cavities 11a with a material that is highly reflective to the emitted light from the light emitting layer 2. The reflectivity of the material for the conductive reflecting layers 11 is higher than that of the first main face 1a of the conductive substrate 1. The material for the conductive reflecting layers 11 may be a metal or an alloy that is higher in reflectivity than the first main face 1a of the conductive substrate 1.

As shown in FIG. 2, the conductive reflecting layers 11 are disposed outside the first main face 1a of the conductive substrate 1. The conductive reflecting layers 11 have side walls that are aligned in plan view to side walls of the conductive substrate 1. The conductive reflecting layers 11 are shown on the side walls of the conductive substrate 1. Further, the side walls of the conductive reflecting layers 11 are aligned in plan view to the side walls of the light emitting layer 2. The conductive reflecting layers 11 extend inwardly from the side walls of the conductive substrate 1.

As shown in FIG. 2, the semiconductor light emitting device has four corners 31, 32, 33 and 34 in plan view. In some case, each of the conductive reflecting layers 11 extends in the form of a quarter of circle which has the center that is positioned at the corner 31, 32, 33 or 34 as shown in FIG. 2. Namely, four reflecting layers 11 are disposed, which extend from the four corners 31, 32, 33 and 34.

In other cases, two reflecting layers 11 are disposed, which extends opposing two of the four corners 31, 32, 33 and 34.

The conductive reflecting layers 11 are disposed in the cavities 11a. The conductive reflecting layers 11 extend in the areas A. The conductive reflecting layers 11 do not extend in the area B. Adjacent two of the four reflecting layers 11 may partially contact with each other. For example, the conductive reflecting layers 11 including the corner 31 contacts at a position 37 with the conductive reflecting layers 11 including the corner 32. The conductive reflecting layer 11 that includes the corner 32 contacts at a position 36 with the conductive reflecting layer 11 that includes the corner 33. The conductive reflecting layer 11 that includes the corner 33 contacts at a position 38 with the conductive reflecting layer 11 that includes the corner 34.

The contact position at which adjacent two of the conductive reflecting layers 11 contact with each other is not limited to the position on the side walls of the conductive substrate 1. Adjacent two of the conductive reflecting layers 11 may contact with each other at another contact position which is positioned inside the side walls of the conductive substrate 1. The contact position at which adjacent two of the conductive reflecting layers 11 contact with each other is preferably positioned outside the pad electrode 9 in plan view. If the contact position is positioned inside the pad electrode 9 in plan view, then the semiconductor light emitting device would have a reduced function of current diffusion. Thus, it would not be preferable that the contact position is positioned inside the pad electrode 9 in plan view.

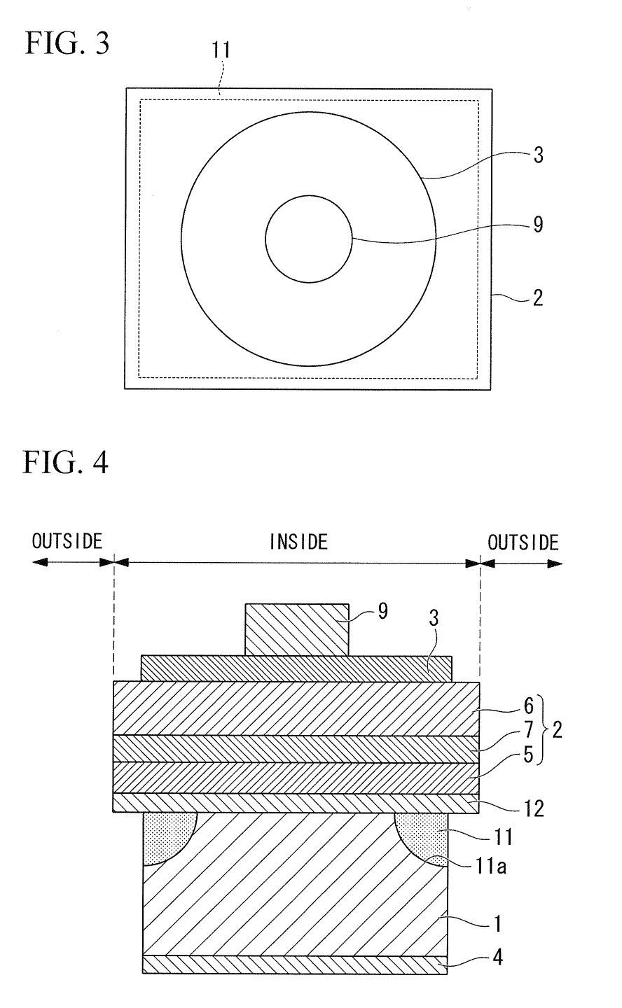

FIG. 3 is a plan view illustrating a modified example of the semiconductor light emitting device of FIG. 1. The semiconductor light emitting device of this modified example shown in FIG. 3 is different in the conductive reflecting layer 11 from the semiconductor light emitting device shown in FIG. 2. As shown in FIG. 3, the semiconductor light emitting device may include a single reflecting layer 11 that extends circumferentially surrounding the first main face 1 a of the conductive substrate 1. In plan view, the single reflecting layer 11 extends outside the pad electrode 9.

As shown in FIG. 3, the side walls of the conductive reflecting layers 11 may be positioned inside the side walls of the light emitting layer 2 in plan view. Namely, the periphery of the conductive reflecting layers 11 may be positioned inside the periphery of the light emitting layer 2 in plan view. In other cases, as shown in FIG. 2, the side walls of the conductive reflecting layers 11 may be aligned to the side walls of the light emitting layer 2 in plan view. Namely, the periphery of the conductive reflecting layers 11 may be aligned to the periphery of the light emitting layer 2 in plan view. In other cases, one or more side walls of the conductive reflecting layers 11 may be positioned inside one or more corresponding side walls of the light emitting layer 2 in plan view, while the remaining side wall or side walls of the conductive reflecting layers 11 may be aligned to one or more corresponding side walls of the light emitting layer 2.

The conductive reflecting layers 11 may preferably have a resistance value that is smaller than a sheet resistance of the conductive substrate 1. In some cases, the buffer layer 12 may not be disposed. The first cladding layer 5 of the light emitting layer 2 may be made of an N-type semiconductor. In this case, the conductive reflecting layer 11 may preferably be made of a material that has a small work function. The conductive reflecting layer 11 may preferably be made of a material that includes at least any one of silver (Ag), aluminum (Al), and gold (Au).

If the first cladding layer 5 of the light emitting layer 2 may be made of an N-type semiconductor, then the conductive reflecting layer 11 may preferably be made of a material that has a large work function. The conductive reflecting layer 11 may preferably be made of a material that includes at least any one of rhodium (Rh), nickel (Ni), palladium (Pa), and platinum (Pt).

As shown in FIG. 1, the semiconductor light emitting device has first and second current paths i1 and i2. The first and second current paths i1 and i2 are established from the pad electrode 9 to the second electrode 4. The first current path i1 passes through the conductive reflecting layer 11. The second current path i1 does not pass through the conductive reflecting layer 11. Namely, the first current path i1 is established from the pad electrode 9 through the first electrode 3, the light emitting layer 2, the buffer layer 12, the conductive reflecting layer 11, and the conductive substrate 1 to the second electrode 4. The second current path i2 is established from the pad electrode 9 through the first electrode 3, the light emitting layer 2, the buffer layer 12, and the conductive substrate 1 to the second electrode 4. The first current path i1 has a lower resistance than the second current path i2, thereby diffusing the current from the pad electrode 9 to the second electrode 4. Part of the current flows on the first current path i1, while other part of the current flows on the second current path i2.

If the conductive reflecting layers 11 have a resistance value that is higher than a sheet resistance of the conductive substrate 1, then the majority of current is likely to flow on the second current path i2 while the minority of the current is likely to flow on the first current path i1. The center area of the activation layer 7 emits strong beams of light upwardly and downwardly. The strong beam of light travels upwardly from the activation layer 7 and reaches the pad electrode 9. The upward traveling of the strong beam of light is then shielded by the pad electrode 9, thereby reducing the efficiency of light emission in the upward direction. A current blocking layer or a current confinement structure may be provided in order to prevent the reduction in the efficiency of light emission in the upward direction.

Preferably, the conductive reflecting layers 11 have a resistance value that is lower than the sheet resistance of the conductive substrate 1. Further preferably, the light emitting layer 2 has a high resistance in horizontal directions parallel to the surfaces of the light emitting layer 2. Then, the majority of current is likely to flow on the first current path i1 while the minority of the current is likely to flow on the first current path i2, whereby the non-center area of the activation layer 7 emits strong beams of light upwardly and downwardly. The upwardly-traveling strong beam of light is then emitted without being shielded by the pad electrode 9, thereby ensuring high efficiency of light emission in the upward direction. No current blocking layer or current confinement structure is needed. The downward-traveling strong beam of light is then reflected by the conductive reflecting layers 11, thereby causing an upwardly-traveling strong beam of light, or causing both upwardly-traveling and horizontally-traveling beams of light. The strong beams of light are not absorbed by the conductive substrate 1, thereby ensuring the high efficiency of light emission in the upward direction.

The wavelength of the beams of light that is emitted from the light emitting layer 2 depends on the semiconductor materials for the light emitting layer 2. The conductive material for the conductive reflecting layer 11 may be selected in light of the wavelength of the beams of light that are emitted from the light emitting layer 2 so that the downwardly-traveling beam of light having been emitted from the light emitting layer 2 is reflected by the conductive reflecting layer 11 without being absorbed into the conductive substrate 1.

The buffer layer 12 extends over the first main face 1a in the area D and the conductive reflecting layers 11 in the areas A. The buffer layer 12 may be formed by epitaxial growth. The buffer layer 12 buffers a strain that is caused by the difference in lattice constant between the conductive substrate 1 and the light emitting layer 2. The buffer layer 12 allows crystal growth of the light emitting layer 2 on the buffer layer 12. The buffer layer 12 may have a multi-layered structure. For example, the buffer layer 12 has seven layers, wherein the multiplayer structure of the buffer layer 12 has alternating stacks of first and second buffer layers. Namely, the first and second buffer layers are alternately stacked six times and further the first buffer layer is stacked on the top second buffer layer, thereby forming the multilayered structure of the buffer layer 12. The buffer layer 12 includes four of first buffer layer and three of the second buffer layer.

The first buffer layer may be made of Al_{c}M_{d}Ga_{1-c-d}N where 0≦c≦1, 0≦d≦1, 0≦c+d≦1, M is indium (In) or boron (B). The first buffer layer may preferably be made of AlN. The thickness of the first buffer layer may be in the range of 0.2 nm-20 nm, and preferably in the range of 1 nm-5 nm which may cause tunneling effect.

The second buffer layer may be made of AlₑM_{f}Ga_{1-e-f}N where 0≦e≦c≦1, 0≦f≦1, 0≦e+f≦1, M is indium (In) or boron (B). The second buffer layer does not contain aluminum or does contain aluminum but at a lower compositional ratio than that of the first buffer layer. The first buffer layer may preferably be made of GaN. The thickness of the second buffer layer may be 5-50 times as large as that of the first buffer layer. Preferably, the thickness of the second buffer layer may be 10-40 times as large as that of the first buffer layer.

The light emitting layer 2 may be made of Group III-V compound semiconductors. The light emitting layer 2 has a double hetero structure that consists of the first cladding layer 5 of a first conductivity type, the second cladding layer 6 of a second conductivity type, and the activation layer 7 that is interposed between the first and second cladding layers 5 and 6.

The first cladding layer 5 may be made of a Group III-V compound semiconductor that is doped with an N-type impurity. For example, the first cladding layer 5 may be made of N-doped AlₐM_{b}Ga_{1-a-b}N where 0≦a≦1, 0≦b≦1, 0≦a+b≦1, M is indium (In) or boron (B). Preferably, the first cladding layer 5 may be made of a nitride compound semiconductor such as gallium nitride (GaN). Preferably, the first cladding layer 5 may have a thickness of approximately 500 nm.

The activation layer 7 may be made of a Group III-V compound semiconductor free of any impurity. For example, the activation layer 7 may be made of Al_{X}M_{Y}Ga_{1-X-Y}N where 0≦X<1, 0≦Y<1, 0≦X+Y<1, M is indium (In) or boron (B).

The second cladding layer 6 may be made of a Group III-V compound semiconductor that is doped with a P-type impurity. For example, the first cladding layer 5 may be made of P-doped Al_{X}M_{Y}Ga_{1-X-Y}N where 0≦X<1, 0≦Y<1, 0≦X+Y<1, M is indium (In) or boron (B). Preferably, the second cladding layer 6 may be made of a nitride compound semiconductor such as gallium nitride (GaN).

The semiconductor light emitting device needs to have the p-n junction. Thus, the light emitting layer 2 needs to have the p-n junction. The light emitting layer 2 may be modified as long as the light emitting layer 2 has the p-n junction. In some cases, the light emitting layer 2 may be modified to be free of the activation layer 7. In other cases, the light emitting layer 2 may also be modified to include, instead of the activation layer 7, a single quantum well structure that causes tunneling effect. In other cases, the light emitting layer 2 may also be modified to include, instead of the activation layer 7, a multiple quantum well structure that causes tunneling effect.

In some cases, the semiconductor light emitting device may be modified not to include the buffer layer 12, wherein the first cladding layer 5 of N-type conductivity is adjacent to the conductive substrate 1 of P-type conductivity. The interface between the N-type first cladding layer 5 and the P-type substrate 1 forms the hetero junction and an alloyed region. These reduce the voltage drop that appears on the interface between the N-type first cladding layer 5 and the P-type substrate 1 when the semiconductor light emitting device is forward-biased.

In accordance with the above descriptions, the buffer layer 12 is discriminated from the double hetero structure that forms the light emitting layer 2. It is possible that a multi-layered structure that includes at least a structure that emits light would be so called to as a light emitting layer. For example, a light emitting layer might include not only the above-described light emitting layer 2 but also the buffer layer 12.

The first electrode 3 is disposed on the main face of the light emitting layer 2. The first electrode 3 is electrically conductive to the light emitting layer 2. Namely, the first electrode 3 is disposed on the main face of the second cladding layer 6. The first electrode 3 is electrically conductive to the second cladding layer 6. The first electrode 3 may be made of a transparent material so as to allow that the beam of light from the light emitting layer 2 travels through the first electrode 3. The first electrode 3 may have an ohmic contact with the light emitting layer 2. The first electrode 3 may be made of indium tin oxide (ITO). Indium oxide (In₂O₃) is mixed with tin oxide (SnO₂) at about a few percents to prepare indium tin oxide (ITO). The thickness of the first electrode 3 may be about 100 nm.

When the second cladding layer 6 is made of a P-type semiconductor, the first electrode 3 may be made of a metal selected from nickel (Ni), platinum (Pt), palladium (Pd), rhodium (Rh), and gold (Al), or an alloy that contains at least one of those metals. When the second cladding layer 6 is made of an N-type semiconductor, the first electrode 3 may be made of a metal selected from aluminum (Al), titanium (Ti), and gold (Al), or an alloy that contains at least one of those metals.

The pad electrode 9 is disposed on a center area of the first electrode 3. The pad electrode 9 allows an electrical connection to an external device. The pad electrode 9 may be made of gold (Au) or aluminum (Al). The pad electrode 9 is disposed not to cover the entirety of the first electrode 3. In plan view, the first electrode 3 has a first portion that is covered by the pad electrode 9 and a second portion that is shown. The second portion surrounds the first portion. The pad electrode 9 is adapted to carry out wire-bonding process. The thickness of the pad electrode 9 is sufficient to carry out wire-bonding process. For example, the thickness of the pad electrode 9 may be in the range from 100 nm to 100 μm. The pad electrode 9 has almost no transparency to light that has been emitted from the light emitting layer 2. The pad electrode 9 that is bonded with a connection wire has no transparency to light that has been emitted from the light emitting layer 2.

The second electrode 4 is disposed on the second main face 1b of the conductive substrate 1. The second electrode 4 may cover the entirety of the second main face 1b of the conductive substrate 1. The second electrode 4 may be formed on the second main face 1b of the conductive substrate 1 by vacuum evaporation. In some cases, gold (Au) can be deposited on the second main face 1b of the conductive substrate 1 to form the second electrode 4 of gold (Au). In other cases, gold (Au) and germanium (Ga) can be deposited on the second main face 1b of the conductive substrate 1, thereby forming the second electrode 4 of gold (Au) and germanium (Ga). In other cases, gold (Au), germanium (Ga) and nickel (Ni) can be deposited on the second main face 1b of the conductive substrate 1, thereby forming the second electrode 4 of gold (Au), germanium (Ga) and nickel (Ni). The second electrode 4 is electrically and physically connected with the conductive substrate 1.

In some cases, the semiconductor light emitting device can be modified to further include, instead of the second cladding layer 6, a current diffusion layer that is interposed between the activation layer 7 and the first electrode 3. The current diffusion layer may be a known current diffusion layer. In other cases, the semiconductor light emitting device can be modified to further include, instead of the second cladding layer 6, a contact layer that is interposed between the activation layer 7 and the first electrode 3. The contact layer may be a known contact layer. In other cases, the semiconductor light emitting device can be modified to further include a current diffusion layer that is interposed between the activation layer 7 and the first electrode 3, wherein the current diffusion layer is surrounded by the second cladding layer 6, provided that the current diffusion layer is positioned below but in plan view it does not extend beyond the pad electrode 9. In other cases, it is possible to reverse the conductivity type of each of the conductive substrate 1, the first cladding layer 5, the activation layer 7 and the second cladding layer 6.

The shape of each element for the semiconductor light emitting device is optional. For example, the shape in plan view of the pad electrode 9 may be circle, rectangle and other polygonal. The shape in plan view of each of the conductive substrate 1 and the light emitting layer 2 is also optional. The shape in plan view may be rectangle or other polygonal or circle.

FIG. 4 is a fragmentary cross sectional elevation view illustrating a modified example of the semiconductor light emitting device in accordance with a first embodiment of the present invention. The modified semiconductor light emitting device shown in FIG. 4 is different from that of FIG. 1 in view that the edges of the conductive reflecting layers 11 are positioned in plan view inside the edges of the light emitting layer 2. Namely, the semiconductor light emitting device may be modified so that the edges of the conductive reflecting layers 11 are at least partially positioned in plan view inside the edges of the light emitting layer 2.

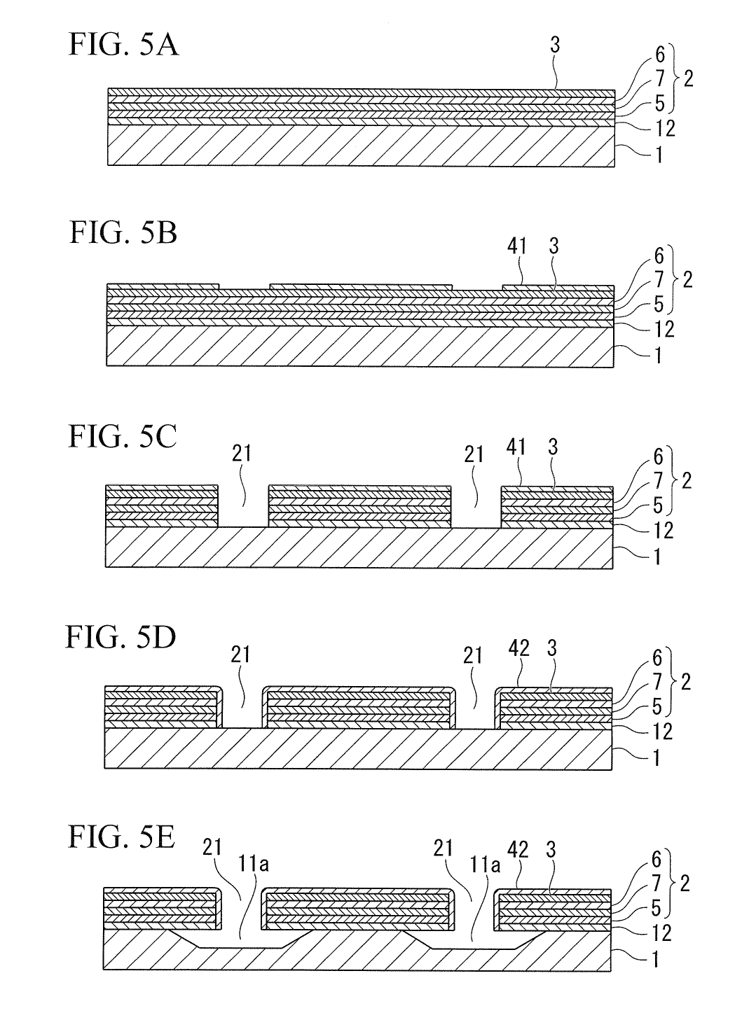

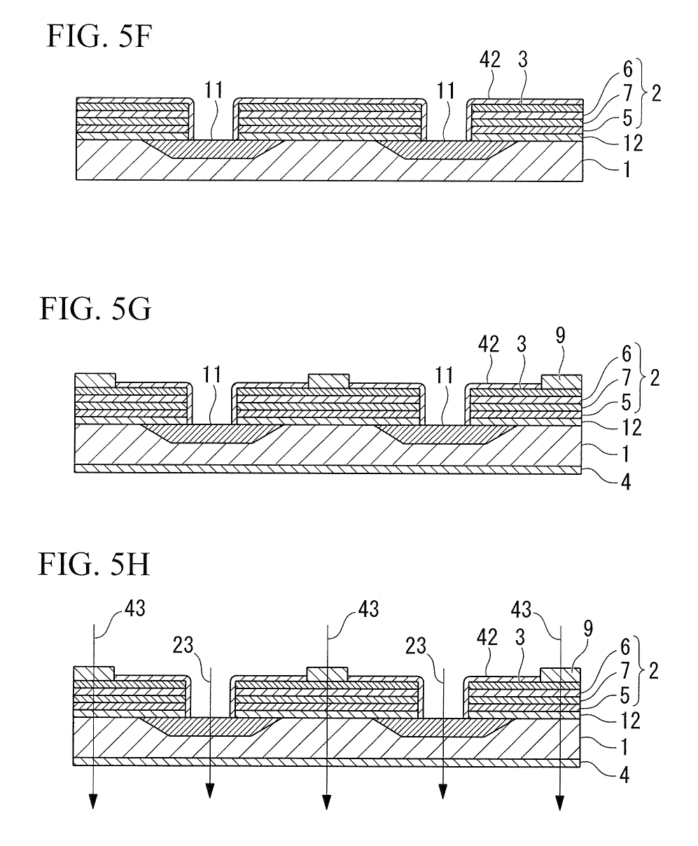

FIGS. 5A through 5H are fragmentary cross sectional elevation views illustrating semiconductor light emitting devices in sequential steps involved in a method of forming the semiconductor light emitting device in accordance with the first embodiment of the present invention.

With reference to FIG. 5A, the conductive substrate 1 is prepared, which has the first and second main faces 1a and 1b. The buffer layer 12 is formed on the first main face 1a of the conductive substrate 1 by a known metal organic chemical vapor deposition method (MOCVD). As described above, the buffer 12 may have the first buffer layer and the second buffer layer. The first buffer layer can be made of aluminum nitride (AlN) layer. Trimethyl aluminum (TMA) and ammonium are supplied to a reaction chamber at predetermined rates, thereby carrying out the metal organic chemical vapor deposition process to form an aluminum nitride (AlN) layer having a predetermined thickness. The second buffer layer can be made of gallium nitride (GaN) layer. Trimethyl gallium (TMG) and ammonium are supplied to the reaction chamber at predetermined rates, thereby carrying out the metal organic chemical vapor deposition process to form a gallium nitride (GaN) layer having a predetermined thickness.

The first cladding layer 5 is formed on the buffer layer 12 by the known metal organic chemical vapor deposition method (MOCVD). The activation layer 7 is then formed on the first cladding layer 5 by the known metal organic chemical vapor deposition method (MOCVD). The second cladding layer 6 is then formed on the activation layer 7 by the known metal organic chemical vapor deposition method (MOCVD). The stack of the first cladding layer 5, the activation layer 7 and the second cladding layer 6 provides the double hetero structure which forms the light emitting layer 2.

The first electrode 3 is formed on the second cladding layer 6 by any available method such as a vacuum evaporation method, a sputtering method and a chemical vapor deposition method. Indium tin oxide is deposited on the second cladding layer 6 to form the first electrode 3 of indium tin oxide on the second cladding layer 6. The first electrode 3 of indium tin oxide has a low resistive contact such as ohmic contact with the second cladding layer 6. The conductive substrate 1 can then be annealed. It is also possible to carry out an anneal process after an evaporation of a metal film for the pad electrode 9 has been carried out.

With reference to FIG. 5B, an oxide film 41 is selectively formed on the second cladding layer 6. The oxide film 41 may be made of SiO₂. The oxide film 41 has openings which are aligned to predetermined positions which correspond to the center of each cavity 11a to be formed in later.

With reference to FIG. 5C, the oxide film 41 with the openings is used as an etching mask to carry out a reactive ion etching process as a type of dry etching process, thereby selectively removing the first electrode 3, the light emitting layer 2 and the buffer layer 12. As a result of the reactive ion etching process, U-shaped grooves 21 as through-holes are formed in the stack over the conductive substrate 1, where the openings are positioned at the center of each cavity 11a to be formed in later. Parts of the first main face 1a of the conductive substrate 1 are shown through the U-shaped grooves 21 as through-holes. In other words, the bottom of each groove 21 is defined by the first main face 1a of the conductive substrate 1. The U-shaped grooves 21 as through-holes may have a width in the range of 200 nm to 100 μm, and preferably in the range of 1 μm to 3 μm. The oxide film 41 used as the mask is then removed.

With reference to FIG. 5D, another oxide film 42 made of SiO2 is selectively formed, which covers the surfaces of the first electrode 3 and the side walls of the U-shaped grooves 21 as through-holes. The oxide film 42 does not over the bottoms of the U-shaped grooves 21 as through-holes so that the parts of the first main face 1a of the conductive substrate 1 are shown through the U-shaped grooves 21 as through-holes.

With reference to FIG. 5E, an etchant is prepared. The etchant may be a solution containing a hydrofluoric acid (HF) and a nitric acid (NHO₃) when the conductive substrate 1 is a silicon substrate. The oxide film 42 is used as a mask to selectively contact the etchant with the shown parts of the first main face 1a of the conductive substrate 1, thereby selectively etching the conductive substrate 1. The conductive substrate 1 is selectively and isotropically etched from the shown parts of the first main face 1 thereof. As a result of the wet etching process, cavities 11a are formed in the conductive substrate 1. The centers of the cavities 11a are positioned under the centers of the U-shaped grooves 21 as through-holes. The cavities 11a do extend horizontally beyond the width of the U-shaped grooves 21 as through-holes. Namely, the cavities 11a do extend horizontally under parts of the light emitting layer 2.

With reference to FIG. 5F, an electrolytic plating process is carried out to fill the cavities 11a with a conductive material such as silver (Ag), thereby forming the conductive reflecting layers 11 in the cavities 11a. Metals such as silver are unlikely to be deposited on the silicon oxide film, while the metals such as silver are likely to be deposited on the conductive substrate 1 and the light emitting layer 2. Namely, the electrolytic plating process is carried out under conditions such that silver is deposited on the cavity walls of the conductive substrate 1, while silver is not adhered on the silicon oxide film 42. The side walls of the U-shaped grooves 21 as through-holes are covered by the silicon oxide film 42. In a case, the electrolytic plating process may excessively be carried out so that the silver is deposited to not only fill up the cavities 11a but partially fill the U-shaped grooves as through-holes. However, no leak current flows between silver and the light emitting layer 2 via the silicon oxide film 42. Preferably, the electrolytic plating process is carried out to fill up the cavities 11a with silver but not to fill the U-shaped grooves as through-holes partially or entirely.

With reference to FIG. 5G, the silicon oxide film 42 is selectively removed to form an opening in the silicon oxide film 42 so that a part of the first electrode 3 is shown through the opening. A metal such as gold (Au) is deposited on the shown part of the first electrode 3, thereby forming the pad electrodes 9 on the first electrode 3. The second electrode 4 is formed on the second main face 1b of the conductive substrate 1 by a vacuum evaporation process. An anneal process is carried out at a predetermined temperature for a predetermined time period.

With reference to FIG. 5H, the conductive substrate 1 is diced by a cutter along arrow marks 23 which penetrate the conductive reflecting layers 11 in the cavities 11a. The cutter may be a diamond cutter. It is also possible as a modification that the conductive substrate 1 is diced by a cutter along other arrow marks 43 which penetrate the pad electrodes 9.

If the side edges of the conductive substrate 1 and the conductive reflecting layers 11 are positioned in plan view outside the edge edges of the light emitting layer 2, the side edges of the conductive substrate 1 and the conductive reflecting layers 11 are etched so that the side edges of the conductive substrate 1 and the conductive reflecting layers 11 are aligned in plan view to the edge edges of the light emitting layer 2, thereby completing the semiconductor light emitting device of FIG. 1. It is also possible as a modification that the side edges of the conductive substrate 1 and the conductive reflecting layers 11 are over-etched so that the side edges of the conductive substrate 1 and the conductive reflecting layers 11 are positioned in plan view inside the edge edges of the light emitting layer 2, thereby completing the modified semiconductor light emitting device of FIG. 4.

In accordance with the above-described embodiments, the semiconductor light emitting device can be formed so that the conductive reflecting layers are formed without carrying out any process for combining a substrate with a layered structure. If the semiconductor light emitting device is formed through the process for combining the substrate with the layered structure, then the luminance property of the device may depend on the adhesiveness between the substrate and the layered structure. If the semiconductor light emitting device is formed without carrying out the process for combining the substrate with the layered structure, then the luminance property of the device can be ensured and there is no problem with the adhesiveness between the substrate and the layered structure.

It is assumed that the epitaxial growth processes are carried out after the reflecting layers 11 are formed. Namely, the light emitting layer 2 is epitaxially grown over the reflecting layers 11. In this case, however, it is not easy to obtain high crystal quality of the light emitting layer 2 over the reflecting layers 11. The luminance property of the light emitting layer 2 depends on the crystal quality of the light emitting layer 2. The light emitting layer 2 over the reflecting layers 11 is unlikely to have desired luminance properties.

In accordance with this embodiment, the conductive reflecting layers 11 are formed after the light emitting layer 2 is epitaxially grown over the conductive substrate 1. It is easy to obtain good crystal quality of the light emitting layer 2. There is an increased flexibility to select a material for the conductive reflecting layers 11 that have low resistive contacts with the light emitting layer and that reflect light that have been emitted from the light emitting layer.

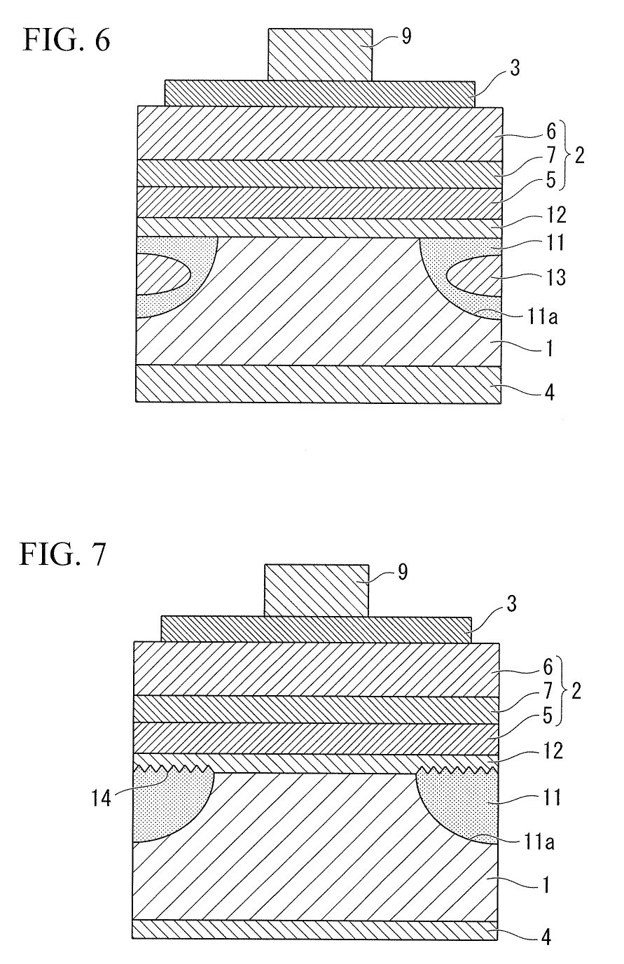

FIG. 6 is a fragmentary cross sectional elevation view illustrating a modified semiconductor light emitting device in accordance with the first embodiment of the present invention. A modified semiconductor light emitting device of FIG. 6 is different from the semiconductor light emitting device of FIG. 1 in reflecting structures in the cavities 11a of the substrate 1. The semiconductor light emitting device of FIG. 1 includes the reflecting structure that is realized by the conductive reflecting layers 11 in the cavities 11a of the substrate 1. The modified semiconductor light emitting device of FIG. 6 includes the reflecting structure that is realized by combinations of the conductive reflecting layers 11 with other reflecting layers 13. The reflecting layers 13 are presented inside the conductive reflecting layers 11. The reflecting layers 13 are separated by the conductive reflecting layers 11 from the conductive substrate 1 and the buffer layer 12. The side walls of the reflecting layers 13 are shown. If the semiconductor light emitting device is modified not to include the buffer layer 12, then the reflecting layers 13 are separated by the conductive reflecting layers 11 from the conductive substrate 1 and the light emitting layer 2. The reflecting layers 13 are different in refractive index from the conductive reflecting layers 11. The reflecting layers 13 are preferably higher in refractive index from the conductive reflecting layers 11. The reflecting layers 13 may be made of conductive or insulating material.

The beam of light that has emitted from the light emitting layer 2 is partially reflected by the conductive reflecting layers 11 and partially transmitted through the conductive reflecting layers 11. The transmitted part of the beam of light reaches the reflecting layers 13 and reflected by the reflecting layers 13. The reflecting layers 13 that are disposed in the conductive reflecting layers 11 increases the efficiency of emission of light from the semiconductor light emitting device.

The conductive reflecting layers 11 and the reflecting layers 13 can be formed as follows. A material for the conductive reflecting layers 11 is deposited on the walls of the cavities 11a so that the conductive reflecting layers 11 having smaller cavities are formed in the cavities 11. Another material for the reflecting layers 13 is deposited to fill up the smaller cavities.

### Second Embodiment

A second embodiment of the present invention will be described. FIG. 7 is a fragmentary cross sectional elevation view illustrating a semiconductor light emitting device in accordance with a second embodiment of the present invention. The semiconductor light emitting device of FIG. 7 is different from the semiconductor light emitting device of FIG. 1 in the interfaces between the buffer layer 12 and the conductive reflecting layers 11. The semiconductor light emitting device of FIG. 7 has irregular interfaces 14 between the buffer layer 12 and the conductive reflecting layers 11, wherein the irregular interfaces 14 have an irregularly. Since the buffer layer 12 has irregular surfaces that face downwardly to the conductive reflecting layers 11, the conductive reflecting layers 11 also has irregular surfaces that face upwardly to the buffer layer 12. However, the semiconductor light emitting device of FIG. 7 has irregularity-free interfaces between the buffer layer 12 and the first main face 1a of the conductive substrate 1.

The semiconductor light emitting device of FIG. 1 has irregularity-free interfaces between the buffer layer 12 and the conductive reflecting layers 11. The beam of light that has been emitted from the light emitting layer 2 would be reflected by the conductive reflecting layers 11 only when the incident angle of the beam of light with reference to the irregularity-free surface of the conductive reflecting layer 11 is larger than a critical angle. If the incident angle is smaller than the critical angle, then the beam of light is not reflected by the conductive reflecting layers 11.

The semiconductor light emitting device of FIG. 7 has the irregular interfaces 14 between the buffer layer 12 and the conductive reflecting layers 11. The irregular interfaces 14 cause irregular reflection of the beam of light that has been emitted from the light emitting layer 2. Irregular reflection by the irregular interfaces 14 leads to the increased reflection of the beam of light, thereby increasing the efficiency of the emission of the beam of light from the semiconductor light emitting device.

The semiconductor light emitting device of FIG. 7 may be modified not to include the buffer layer 12. In this case, the modified semiconductor light emitting device has irregular interfaces between the semiconductor light emitting layer 2 and the conductive reflecting layers 11, wherein the irregular interfaces have an irregularly. Since the semiconductor light emitting layer 2 has irregular surfaces that face downwardly to the conductive reflecting layers 11, the conductive reflecting layers 11 also has irregular surfaces that face upwardly to the semiconductor light emitting layer 2. However, the modified semiconductor light emitting device free of the buffer layer 12 has irregularity-free interfaces between the semiconductor light emitting layer 2 and the first main face 1a of the conductive substrate 1.

The irregular interfaces between the semiconductor light emitting layer 2 and the conductive reflecting layers 11 cause irregular reflection of the beam of light that has been emitted from the light emitting layer 2. Irregular reflection by the irregular interfaces leads to the increased reflection of the beam of light, thereby increasing the efficiency of the emission of the beam of light from the semiconductor light emitting device.

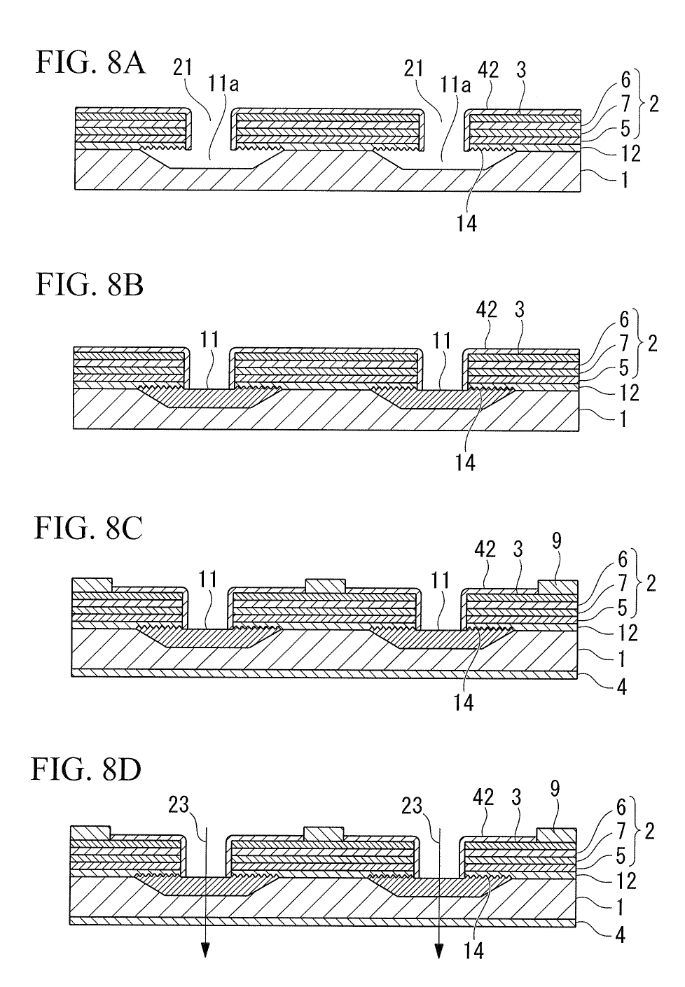

FIGS. 8A through 8D are fragmentary cross sectional elevation views illustrating semiconductor light emitting devices in sequential steps involved in a method of forming the semiconductor light emitting device in accordance with the second embodiment of the present invention. The sequential steps of FIGS. 8A through 8D are carried out following to the sequential steps of FIGS. 5A through 5E. Namely, the semiconductor light emitting device of FIG. 7 can be formed by a set of sequential steps of FIGS. 5A through 5E and FIGS. 8A through 8D.

The above-described processes of FIGS. 5A through 5E are carried out to obtain the substrate structure of FIG. 5E that has the cavities 11a under the U-shaped grooves 21 as through-holes. Duplicate descriptions are omitted.

An etchant is prepared, which contains a phosphoric acid (H₃PO₄) or a potassium hydroxide (KOH). The etchant is heated to about 70° C., thereby preparing a hot etchant. As described above, the oxide film 42 is made of SiO₂. The buffer layer 12 is made of the Group III-V compound semiconductor. The semiconductor light emitting layer 2 is also made of the Group III-V compound semiconductor. The etching rate of SiO₂ of the oxide film 42 is lower than the etching rate of the Group III-V compound semiconductor of the buffer layer 12 or the semiconductor light emitting layer 2. The buffer layer 12 is partially exposed to the cavities 11a as shown in FIG. 8A. The substrate 1 is exposed to the hot etchant, so that the exposed surfaces of the buffer layer 12 are etched by the etchant thereby forming irregular surfaces 14, while the oxide film 42 is not etched by the etchant. The irregular surfaces 14 of the buffer layer 12 face to the cavities 11a.

If the semiconductor light emitting device is modified not to include the buffer layer 12, the semiconductor light emitting layer 2 is partially exposed to the cavities 11a. The substrate 1 is exposed to the hot etchant, so that the exposed surfaces of the semiconductor light emitting layer 2 are etched by the etchant thereby forming irregular surfaces, while the oxide film 42 is not etched by the etchant. The irregular surfaces of the semiconductor light emitting layer 2 face to the cavities 11a.

With reference to FIG. 8B, an electrolytic plating process is carried out to fill the cavities 11a with a conductive material such as silver (Ag), thereby forming the conductive reflecting layers 11 in the cavities 11a. Metals such as silver are unlikely to be deposited on the silicon oxide film, while the metals such as silver are likely to be deposited on the conductive substrate 1 and the light emitting layer 2. Namely, the electrolytic plating process is carried out under conditions such that silver is deposited on the cavity walls of the conductive substrate 1, while silver is not adhered on the silicon oxide film 42. The side walls of the U-shaped grooves 21 as through-holes are covered by the silicon oxide film 42. In a case, the electrolytic plating process may excessively be carried out so that the silver is deposited to not only fill up the cavities 11a but partially fill the U-shaped grooves as through-holes. However, no leak current flows between silver and the light emitting layer 2 via the silicon oxide film 42. Preferably, the electrolytic plating process is carried out to fill up the cavities 11a with silver but not to fill the U-shaped grooves as through-holes partially or entirely. Since the buffer layer 12 has the irregular surfaces 14 that face to the cavities 11a, the conductive reflecting layers 11 also has irregular surfaces that interface with the irregular surfaces 14 of the buffer layer 12. However, there is an irregularity-free interface between the buffer layer 12 and the first main face 1a of the conductive substrate 1.

With reference to FIG. 8C, the silicon oxide film 42 is selectively removed to form an opening in the silicon oxide film 42 so that a part of the first electrode 3 is shown through the opening. A metal such as gold (Au) is deposited on the shown part of the first electrode 3, thereby forming the pad electrodes 9 on the first electrode 3. The second electrode 4 is formed on the second main face 1b of the conductive substrate 1 by a vacuum evaporation process. An anneal process is carried out at a predetermined temperature for a predetermined time period.

With reference to FIG. 8D, the conductive substrate 1 is diced by a cutter along arrow marks 23 which penetrate the conductive reflecting layers 11 in the cavities 11a. The cutter may be a diamond cutter. It is also possible as a modification that the conductive substrate 1 is diced by a cutter along other arrow marks 43 which penetrate the pad electrodes 9.

If the side edges of the conductive substrate 1 and the conductive reflecting layers 11 are positioned in plan view outside the edge edges of the light emitting layer 2, the side edges of the conductive substrate 1 and the conductive reflecting layers 11 are etched so that the side edges of the conductive substrate 1 and the conductive reflecting layers 11 are aligned in plan view to the edge edges of the light emitting layer 2, thereby completing the semiconductor light emitting device of FIG. 7. It is also possible as a modification that the side edges of the conductive substrate 1 and the conductive reflecting layers 11 are over-etched so that the side edges of the conductive substrate 1 and the conductive reflecting layers 11 are positioned in plan view inside the edge edges of the light emitting layer 2, thereby completing the modified semiconductor light emitting device.

In accordance with this embodiment, the semiconductor light emitting device of FIG. 7 may be modified not to include the buffer layer 12. In this case, the modified semiconductor light emitting device has irregular interfaces between the semiconductor light emitting layer 2 and the conductive reflecting layers 11, wherein the irregular interfaces have an irregularly. Since the semiconductor light emitting layer 2 has irregular surfaces that face downwardly to the conductive reflecting layers 11, the conductive reflecting layers 11 also has irregular surfaces that face upwardly to the semiconductor light emitting layer 2. However, the modified semiconductor light emitting device free of the buffer layer 12 has irregularity-free interfaces between the semiconductor light emitting layer 2 and the first main face 1a of the conductive substrate 1.

The irregular interfaces between the semiconductor light emitting layer 2 and the conductive reflecting layers 11 cause irregular reflection of the beam of light that has been emitted from the light emitting layer 2. Irregular reflection by the irregular interfaces leads to the increased reflection of the beam of light, thereby increasing the efficiency of the emission of the beam of light from the semiconductor light emitting device.

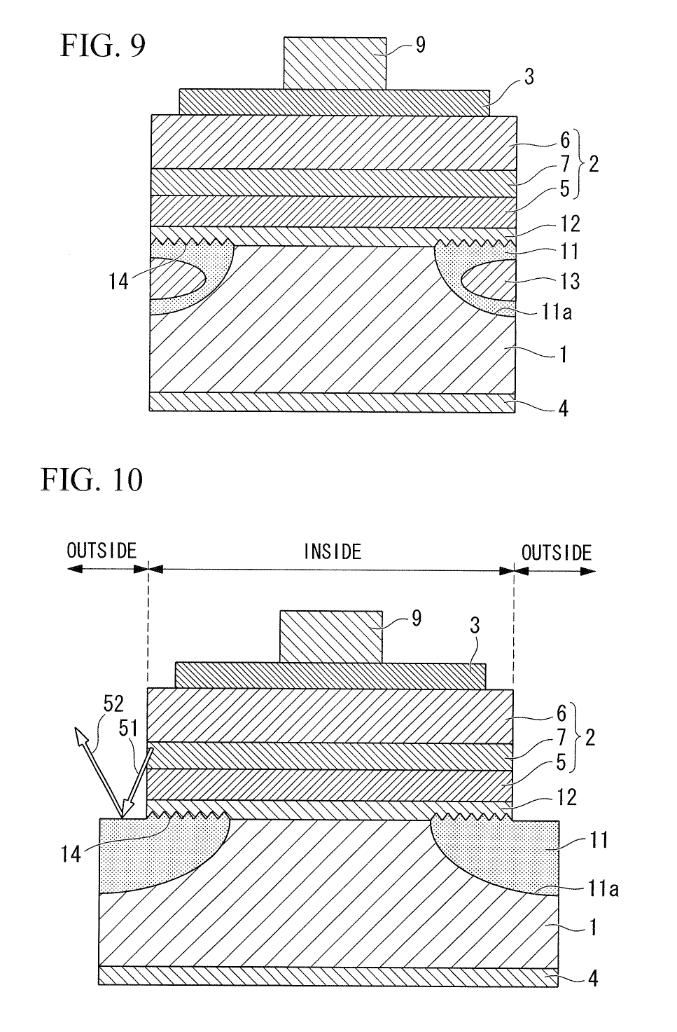

FIG. 9 is a fragmentary cross sectional elevation view illustrating a modified semiconductor light emitting device in accordance with the second embodiment of the present invention. A modified semiconductor light emitting device of FIG. 9 is different from the semiconductor light emitting device of FIG. 7 in reflecting structures in the cavities 11a of the conductive substrate 1. The semiconductor light emitting device of FIG. 7 includes the reflecting structure that is realized by the conductive reflecting layers 11 in the cavities 11a of the conductive substrate 1. The modified semiconductor light emitting device of FIG. 9 includes the reflecting structure that is realized by combinations of the conductive reflecting layers 11 with other reflecting layers 13. The reflecting layers 13 are presented inside the conductive reflecting layers 11. The reflecting layers 13 are separated by the conductive reflecting layers 11 from the conductive substrate 1 and the buffer layer 12. The side walls of the reflecting layers 13 are shown. If the semiconductor light emitting device is modified not to include the buffer layer 12, then the reflecting layers 13 are separated by the conductive reflecting layers 11 from the conductive substrate 1 and the light emitting layer 2. The reflecting layers 13 are different in refractive index from the conductive reflecting layers 11. The reflecting layers 13 are preferably higher in refractive index from the conductive reflecting layers 11. The reflecting layers 13 may be made of conductive or insulating material.

The beam of light that has emitted from the light emitting layer 2 is partially reflected by the conductive reflecting layers 11 and partially transmitted through the conductive reflecting layers 11. The transmitted part of the beam of light reaches the reflecting layers 13 and reflected by the reflecting layers 13. The reflecting layers 13 that are disposed in the conductive reflecting layers 11 increases the efficiency of emission of light from the semiconductor light emitting device.

The conductive reflecting layers 11 and the reflecting layers 13 can be formed as follows. A material for the conductive reflecting layers 11 is deposited on the walls of the cavities 11a so that the conductive reflecting layers 11 having smaller cavities are formed in the cavities 11. Another material for the reflecting layers 13 is deposited to fill up the smaller cavities.

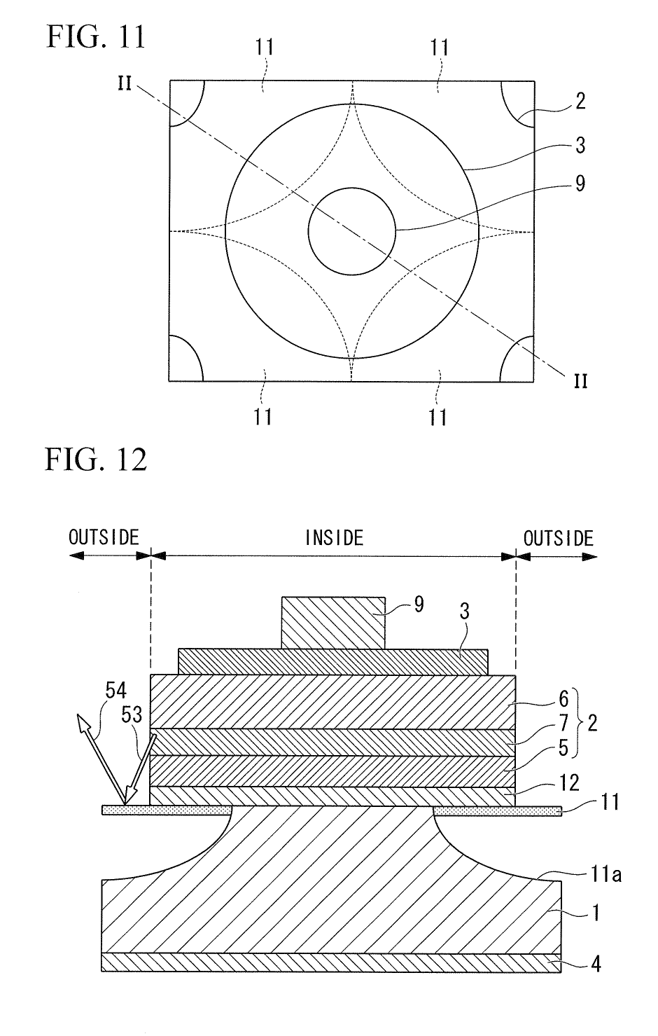

FIG. 10 is a fragmentary cross sectional elevation view illustrating another modified semiconductor light emitting device in accordance with the second embodiment of the present invention. FIG. 11 is a plan view illustrating the other modified semiconductor light emitting device of FIG. 10, which illustrates it taken along a II-II line of FIG. 11. The conductive reflecting layers 11 have the edges that are aligned in plan view to the edges of the conductive substrate 1. The light emitting layer 2 has the edges that are aligned in plan view to the edges of the buffer layer 12. The aligned edges of the light emitting layer 2 and the buffer layer 12 are positioned in plan view inside the aligned edges of the conductive reflecting layers 11 and the conductive substrate 1. In other words, the edges of the conductive reflecting layers 11 are positioned in plan view outside the edges of the light emitting layer 2. The conductive reflecting layers 11 have outside and inside portions, wherein the outside portions are positioned in plan view outside the light emitting layer 2, and the inside portions are overlapped in plan view by the light emitting layer 2.

The other modified semiconductor light emitting device of FIGS. 10 and 11 can be obtained by the processes of FIGS. 5A through 5E and 8A through 8D, provided that in the process of FIG. 8D, the side walls of the conductive reflecting layers 11 and the conductive substrate 1 are not etched after the conductive substrate 1 has been diced.

The light emitting layer 2 emits the beam of light, a part of which travels toward the outside portions of the conductive reflecting layers 11 as shown by an arrow mark 51 in FIG. 10. The partial beam of light is then reflected by the upper surface of the outside portion of the conductive reflecting layer 11. The reflected beam of light travels upwardly as shown by an arrow mark 52 in FIG. 10, thereby improving the efficiency of the emission of light.

No etching process needs to be carried out after the dicing process has been carried out.

It is also possible as a modification that the other modified semiconductor light emitting device of FIG. 10 is further modified to include additional reflecting layers 13 in the conductive reflecting layers 11. The reflecting layers 13 are presented inside the conductive reflecting layers 11. The reflecting layers 13 are separated by the conductive reflecting layers 11 from the conductive substrate 1 and the buffer layer 12. The side walls of the reflecting layers 13 are shown. If the semiconductor light emitting device is modified not to include the buffer layer 12, then the reflecting layers 13 are separated by the conductive reflecting layers 11 from the conductive substrate 1 and the light emitting layer 2. The reflecting layers 13 are different in refractive index from the conductive reflecting layers 11. The reflecting layers 13 are preferably higher in refractive index from the conductive reflecting layers 11. The reflecting layers 13 may be made of conductive or insulating material.

The beam of light that has emitted from the light emitting layer 2 is partially reflected by the conductive reflecting layers 11 and partially transmitted through the conductive reflecting layers 11. The transmitted part of the beam of light reaches the reflecting layers 13 and reflected by the reflecting layers 13. The reflecting layers 13 that are disposed in the conductive reflecting layers 11 increases the efficiency of emission of light from the semiconductor light emitting device.

The conductive reflecting layers 11 and the reflecting layers 13 can be formed as follows. A material for the conductive reflecting layers 11 is deposited on the walls of the cavities 11a so that the conductive reflecting layers 11 having smaller cavities are formed in the cavities 11. Another material for the reflecting layers 13 is deposited to fill up the smaller cavities.

### Third Embodiment

A third embodiment of the present invention will be described. FIG. 12 is a fragmentary cross sectional elevation view illustrating a semiconductor light emitting device in accordance with a third embodiment of the present invention. The semiconductor light emitting device of FIG. 12 is different from the semiconductor light emitting device of FIG. 1 in that the conductive reflecting layers 11 are in the shape of a film. Namely, the film-shaped conductive reflecting layers 11 do not fill up the cavities 11a of the conductive substrate 1. The film-shaped conductive reflecting layers 11 extend under the buffer layer 12 and over vacant cavities 11a of the conductive substrate 1. The vacant cavities 11a have open sides. The film-shaped conductive reflecting layers 11 have inside and outside portions. The inside portions of the film-shaped conductive reflecting layers 11 extend under the buffer layer 12. The outside portions of the film-shaped conductive reflecting layers 11 extend outside the buffer layer 12. The inside and outside portions of the film-shaped conductive reflecting layers 11 extend over the vacant cavities 11a.

The vacant cavities 11a have cavity walls which are separated from the film-shaped conductive reflecting layers 11 shown in FIG. 12. In some cases, each cavity 11a of FIG. 12 may be modified as long as the cavity wall is at least partially separated from the film-shaped conductive reflecting layer 11. In other words, each cavity 11a of FIG. 12 may be modified as long as the bottom surface of the film-shaped conductive reflecting layer 11 is at least partially separated from the cavity wall of the cavity 11a.

The conductive substrate 1 of FIG. 12 has a mechanical contact area with the buffer layer 12, where the mechanical contact area means an area through which a mechanical stress is transmitted between the conductive substrate 1 and the buffer layer 12. The mechanical contact area of the conductive substrate 1 of FIG. 12 corresponds to a physical contact area between the substrate 1 and the buffer layer 12. The mechanical stress is caused by the difference in linear expansion coefficient between the buffer layer 12 and the conductive substrate 1. In contrast, the conductive substrate 1 of FIG. 1 has another mechanical contact area with the buffer layer 12, where the mechanical contact area corresponds to not only the physical contact area between the substrate 1 and the buffer layer 12 but also another physical contact area between the conductive reflecting layers 12 and the buffer layer 12. Thus, the vacant cavities 11a of the conductive substrate 1 of FIG. 12 reduce the mechanical contact area, thereby reducing the mechanical stress between the conductive substrate 1 and the buffer layer 12.

The semiconductor light emitting device can also be modified not to include the buffer layer 12. In this case, the conductive substrate 1 has a mechanical contact area with the light emitting layer 2, where the mechanical contact area means an area through which a mechanical stress is transmitted between the conductive substrate 1 and the light emitting layer 2. The mechanical contact area of the conductive substrate 1 corresponds to a physical contact area between the substrate 1 and the light emitting layer 2. The mechanical stress is caused by the difference in linear expansion coefficient between the light emitting layer 2 and the conductive substrate 1. Thus, the vacant cavities 11a reduce the mechanical contact area, thereby reducing the mechanical stress between the conductive substrate 1 and the light emitting layer 2.

The film-shaped conductive reflecting layers 11 have the edges that are aligned in plan view to the edges of the conductive substrate 1. The light emitting layer 2 has the edges that are aligned in plan view to the edges of the buffer layer 12. The aligned edges of the light emitting layer 2 and the buffer layer 12 are positioned in plan view inside the aligned edges of the film-shaped conductive reflecting layers 11 and the conductive substrate 1. In other words, the edges of the film-shaped conductive reflecting layers 11 are positioned in plan view outside the edges of the light emitting layer 2. The film-shaped conductive reflecting layers 11 have outside and inside portions, wherein the outside portions are positioned in plan view outside the light emitting layer 2, and the inside portions are overlapped in plan view by the light emitting layer 2.

The light emitting layer 2 emits the beam of light, a part of which travels toward the outside portions of the film-shaped conductive reflecting layers 11 as shown by an arrow mark 53 in FIG. 12. The partial beam of light is then reflected by the upper surface of the outside portion of the film-shaped conductive reflecting layer 11. The reflected beam of light travels upwardly as shown by an arrow mark 54 in FIG. 12, thereby improving the efficiency of the emission of light.

The semiconductor light emitting device of FIG. 12 can be obtained without carrying out the etching process for etching the side edges of the conductive substrate 1 after the conductive substrate 1 has been diced.

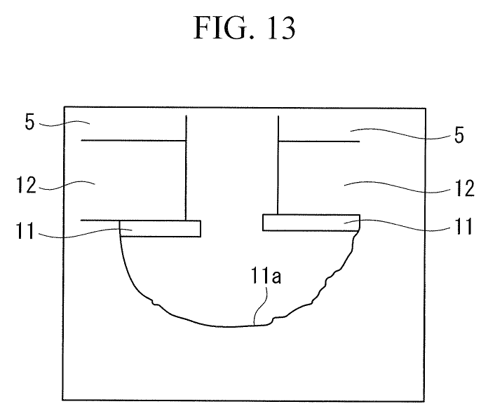

FIG. 13 is a fragmentary cross sectional elevation view illustrating a cavity of a conductive substrate before the dicing process involved in the method of forming the light emitting device of FIG. 12. In some cases, the film-shaped conductive reflecting layers 11 may extend over the cavity 11a. The film-shaped conductive reflecting layers 11 may have edges which are positioned in plan view inside the groove which is defined by the buffer layer 12 and the first cladding layer 5. Namely, the edges of the film-shaped conductive reflecting layers 11 may be shown through the groove as a through-hole. Thus, the film-shaped conductive reflecting layers 11 may have projecting portions which extend under the groove as a through-hole. The projecting portions have poor mechanical strength. In the fabrication processes for the semiconductor light emitting device, the projecting portions may be removed unwillingly. Whereas the edges of the conductive substrate 1 are positioned in plan view outside the edges of the light emitting layer 2, the film-shaped conductive reflecting layers 11 may in some cases have the edges which are positioned in plan view inside the edges of the conductive substrate 1.

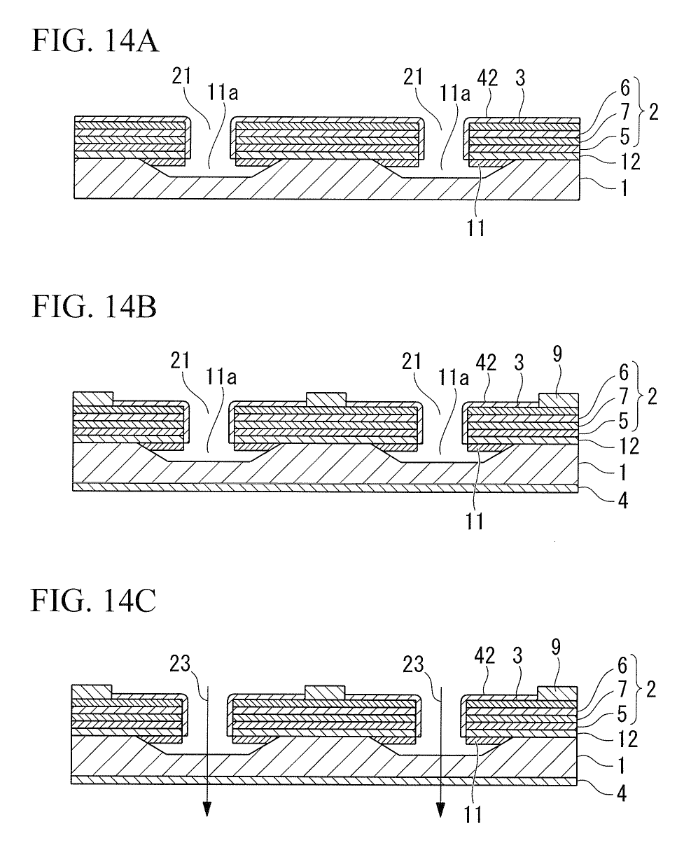

FIGS. 14A through 14C are fragmentary cross sectional elevation views illustrating semiconductor light emitting devices in sequential steps involved in a method of forming the semiconductor light emitting device in accordance with the third embodiment of the present invention. The sequential steps of FIGS. 14A through 14C are carried out following to the sequential steps of FIGS. 5A through 5E. Namely, the semiconductor light emitting device of FIG. 13 can be formed by a set of sequential steps of FIGS. 5A through 5E and FIGS. 14A through 14C.

The above-described processes of FIGS. 5A through 5E are carried out to obtain the substrate structure of FIG. 5E that has the cavities 11a under the U-shaped grooves 21 as through-holes. Duplicate descriptions are omitted.

With reference to FIG. 14A, the buffer layer 12 has inside and outside portions. The inside portion of the buffer layer 12 extends over the first main face of the conductive substrate 1. The outside portion of the buffer layer 12 extends over the cavity 11a. The bottom surface of the outside portion of the buffer layer 12 faces to the cavity 11a. An electrolytic plating process is carried out to plate a conductive material such as silver (Ag) onto the bottom surface of the outside portion of the buffer layer 12, thereby forming the film-shaped conductive reflecting layers 11 on the bottom surface of the outside portion of the buffer layer 12.

Metals such as silver are highly adhesive on metals. Metals such as silver are adhesive on compound semiconductors. Metals such as silver are poorly adhesive on silicon. Metals such as silver are not adhesive on silicon dioxide. Namely, the electrolytic plating process is carried out under conditions such that silver is deposited on the compound semiconductor, while silver is not adhered on silicon and silicon oxide. The buffer layer 12 is made of a compound semiconductor. The semiconductor light emitting layer 2 is made of compound semiconductors. The conductive substrate 1 is made of silicon. Thus, silver is deposited only the bottom surface of the outside portion of the buffer layer 12, while no deposition of silver appears on the cavity wall 11a of the conductive substrate 1 and on the silicon oxide film 42. The film-shaped conductive reflecting layers 11 extend under the outside portion of the buffer layer 12 and over the cavities 11a.

With reference to FIG. 14B, the silicon oxide film 42 is selectively removed to form an opening in the silicon oxide film 42 so that a part of the first electrode 3 is shown through the opening. A metal such as gold (Au) is deposited on the shown part of the first electrode 3, thereby forming the pad electrodes 9 on the first electrode 3. The second electrode 4 is formed on the second main face 1b of the conductive substrate 1 by a vacuum evaporation process. An anneal process is carried out at a predetermined temperature for a predetermined time period.

With reference to FIG. 14C, the conductive substrate 1 is diced by a cutter along arrow marks 23 which penetrate the conductive reflecting layers 11 in the cavities 11a. The cutter may be a diamond cutter. It is also possible as a modification that the conductive substrate 1 is diced by a cutter along other arrow marks 43 which penetrate the pad electrodes 9. The side edges of the conductive substrate 1 are positioned in plan view outside the edge edges of the light emitting layer 2.

In accordance with this embodiment, the semiconductor light emitting device of FIG. 13 may be modified not to include the buffer layer 12. In this case, the semiconductor light emitting layer 2 has inside and outside portions. The inside portion of the semiconductor light emitting layer 2 extends over the first main face of the conductive substrate 1. The outside portion of the semiconductor light emitting layer 2 extends over the cavity 11a. The bottom surface of the outside portion of the semiconductor light emitting layer 2 faces to the cavity 11a. An electrolytic plating process is carried out to plate a conductive material such as silver (Ag) onto the bottom surface of the outside portion of the semiconductor light emitting layer 2, thereby forming the film-shaped conductive reflecting layers 11 on the bottom surface of the outside portion of the semiconductor light emitting layer 2.

The electrolytic plating process is carried out under conditions such that silver is deposited on the compound semiconductor, while silver is not adhered on silicon and silicon oxide. The semiconductor light emitting layer 2 is made of a compound semiconductor. The conductive substrate 1 is made of silicon. Thus, silver is deposited only the bottom surface of the outside portion of the semiconductor light emitting layer 2, while no deposition of silver appears on the cavity wall 11a of the conductive substrate 1 and on the silicon oxide film 42. The film-shaped conductive reflecting layers 11 extend under the outside portion of the semiconductor light emitting layer 2 and over the cavities 11a.

### Fourth Embodiment

A fourth embodiment of the present invention will be described. The fourth embodiment provides a composite semiconductor device that includes a combination of the semiconductor light emitting device with a protective device that protects the semiconductor light emitting device. The light emitting device including the light emitting layer of compound semiconductors may often have low electrostatic discharge voltage. For example, application of a high surge voltage over 100V to the semiconductor light emitting device may break the semiconductor light emitting device. For the purpose of electrostatic discharge protection, the protective device and the semiconductor light emitting device may be mounted together on the same package. The protective device is designed to protect the semiconductor light emitting device. The protective device may be realized by at least a diodes or at least a capacitor.

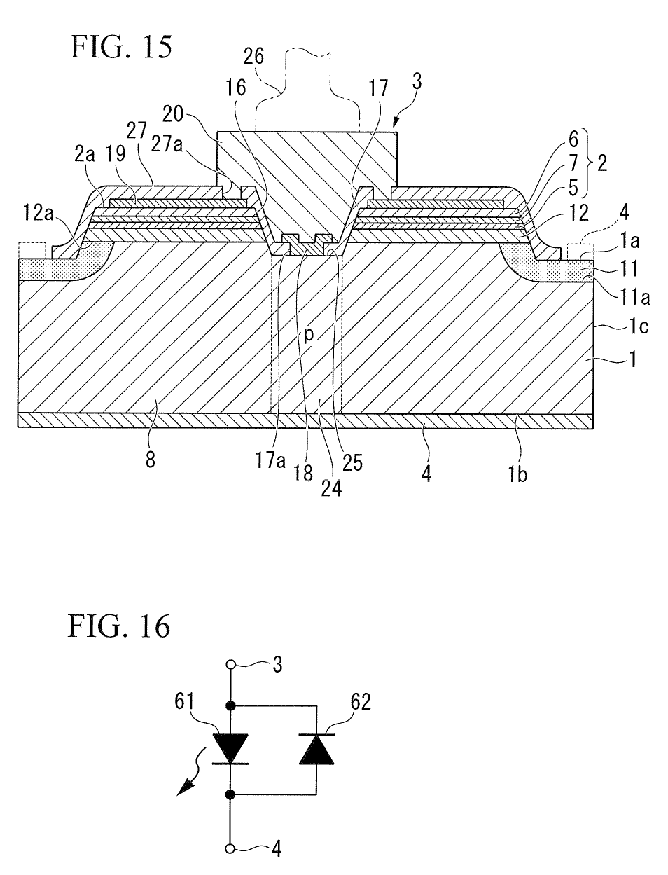

FIG. 15 is a fragmentary cross sectional elevation view illustrating a composite semiconductor device in accordance with a fourth embodiment of the present invention. The composite semiconductor device may include a semiconductor light emitting device and a protective device. The semiconductor light emitting device may include a light emitting diode. The protective device may include a Schottky barrier diode. The semiconductor light emitting device and the protective device are formed on a conductive substrate 1. The conductive substrate 1 has a first region 8 and a second region 24 surrounded by the first region 8. The first region 8 of the conductive substrate 1 provides a substrate region for the semiconductor light emitting device. The second region 24 of the conductive substrate 1 provides a substrate region for the protective device.

The semiconductor light emitting device may include the first region 8 of the conductive substrate 1, the buffer layer 12, the semiconductor light emitting layer 2, the conductive reflecting layer 11, a light-transparent conductive film 19, and the first and second electrodes 3 and 4. The protective device may include the second region 24 of the conductive substrate 1, a Schottky contact metal layer 18, and the first and second electrodes 3 and 4. The stack of the buffer layer 12 and the semiconductor light emitting layer 2 forms a compound semiconductor light epitaxial layer.

In some cases, the conductive substrate 1 may be a p-type single crystal silicon substrate that contains a p-type impurity. The p-type impurity may be a Group III element such as boron (B). The conductive substrate 1 may have first and second main faces 1a and 1b opposing each other. The conductive substrate 1 has the first and second regions for the semiconductor light emitting device and the protective device, respectively. The second region 24 is positioned at the center of the conductive substrate 1, while the first region 8 surrounds the second region 24.

In some cases, the conductive substrate 1 may have a p-type impurity concentration in the range of approximately 5E18 [cm⁻³] to approximately 5E19 [cm⁻³]. The conductive substrate 1 may have a resistivity in the range of approximately 0.0001 [Ωcm] to approximately 0.01 [Ωcm]. The conductive substrate 1 may provide a current path for the semiconductor light emitting device and the protective device. Namely, the second region 24 of the conductive substrate 1 performs as a body of the Schottky barrier diode, wherein the body provides a current path for the Schottky barrier diode. The first region 8 of the conductive substrate 1 surrounds the second region 24. The first region 8 of the conductive substrate 1 provides a current path for the light emitting diode. The conductive substrate 1 further performs as a substrate for epitaxial growth of the buffer layer 12 and the semiconductor light emitting layer 2. The conductive substrate 1 mechanically supports the semiconductor light emitting layer 2 and the first electrode 3.

In some cases, the conductive substrate 1 has the first main face 1a which may include a center recess 25, a side recess, and a flat portion which separates the center recess 25 from the side recess. The center recess 25 is positioned at the center of the first main face 1a of the conductive substrate 1. In plan view, the flat portion surrounds the center recess 25. In plan view, the side recess surrounds the flat portion. The side recess defines the periphery edge of the first main face 1a of the conductive substrate 1.

In other cases, the conductive substrate 1 can be modified to have a modified main face 1a that is flat entirely.

In other cases, it is possible as a modification that the conductivity type of the conductive substrate 1 is an n-type.

In other cases, the conductive substrate 1 can be modified such that the first region 8 for the light emitting device is higher in impurity concentration than the second region 24 for the protective device. In this case, the first region 8 is lower in resistivity than the second region 24. Reducing the resistivity of the first region 8 can reduce the voltage drop that appears in the first region 8 when the light emitting device is operated.

The compound semiconductor epitaxial layer includes the buffer layer 12 and the light emitting layer 2. In other words, the compound semiconductor epitaxial layer has a multi-layered hetero structure that includes plural Group III-V compound semiconductor layers. The light emitting layer 2 includes the first cladding layer 5, the activation layer 7, and the second cladding layer 6. The compound semiconductor epitaxial layer has a center hole 16 which penetrates through the compound semiconductor epitaxial layer. Namely, the center hole 16 penetrates through the stack of the light emitting layer 2 and the buffer layer 12. The compound semiconductor epitaxial layer has an upper surface that is an upper main face 2a of the light emitting layer 2. The compound semiconductor epitaxial layer has a lower surface that is a lower main face 12a of the buffer layer 12. The center hole 16 communicates with the center recess 25 of the conductive substrate 1.

The center hole 16 and the center recess 25 may be formed by selectively etching the compound semiconductor epitaxial layer and the conductive substrate 1, after the compound semiconductor epitaxial layer is epitaxially grown on the main face 1a of the conductive substrate 1. If the conductive substrate is made of silicon, then the center recess has side and bottom walls of silicon. The center hole 16 and the center recess 25 forms a combined hole. The combined hole has a tapered side wall so that the combined hole is tapered in the direction of depth. Namely, the combined hole decreases in horizontally sectioned area as the depth thereof increases. The combined hole is positioned over the second region 24 of the conductive substrate 1. An insulating layer 17 is formed on the tapered side wall of the combined hole that includes the center hole 16 and the center recess 25.

The first electrode 3 includes a transparent conductive film 19 as a first part and a bonding pad 20 as a second part. The bonding pad 20 is electrically connected to the transparent conductive film 19. A Schottky metal layer 18 is disposed between the bonding pad 20 and the second region 24 of the conductive substrate 1. The Schottky metal layer 18 is disposed on the bottom wall of the combined hole, namely on the top surface of the second region 24 of the conductive substrate 1. The Schottky metal layer 18 is disposed in contact with the top surface of the second region 24 of the conductive substrate 1. The bonding pad 20 is also disposed in contact with the Schottky metal layer 18. The bonding pad 20 provides an electrical connection between the transparent conductive film 19 and the Schottky metal layer 18. The bonding pad 20 also provides another electrical connection to an external element.

The bonding pad 20 has a tapered portion which is in the center hole 16 which has the side wall covered by the insulating film 17. The bonding pad 20 also has a side portion which is positioned over the inside portion of the stack of the transparent conductive film 19 and the light emitting layer 2. The bonding pad 20 is electrically connected via the transparent conductive film 19 to the light emitting layer 2.

It is possible as a modification that the transparent conductive film 19 is not provided so that the side portion of the bonding pad 20 ohmically contacts with the light emitting layer 2. In the absence of the transparent conductive film 19, the side portion of the bonding pad 20 may, if necessary, ohmically contact with the main face 2a of the light emitting layer 2 so as to allow a current flow from the first electrode 3 to the light emitting layer 2. In the absence of the transparent conductive film 19, the side portion of the bonding pad 20 performs as the first part which is eclectically connected with the light emitting layer 2.

The transparent conductive film 19 may allow that a current is uniformly applied to the entire region of the light emitting layer 2. Namely, the transparent conductive film 19 is useful to uniformly apply the current to the entire region of the light emitting layer 2. Actually, however, it is not easy to realize 100% optical transmittance of the transparent conductive film 19. The transparent conductive film 19 with an optical transmittance less than 100% absorbs light. The transparent conductive film 19 with an optical transmittance less than 100% necessarily decreases emission efficiency. In addition, the transparent conductive film 19 necessarily increases the cost of the semiconductor light emitting device. It may be possible to consider whether the transparent conductive film 19 should be provided or not, in light of the emission efficiency and the cost.

The transparent conductive film 19 performs as the first part of the first electrode 3. The transparent conductive film 19 is disposed on the main face 2a of the light emitting layer 2, so that the transparent conductive film 19 ohmically contacts with the main face 2a of the light emitting layer 2. The surface of the second cladding layer 6 constitutes the main face 2a of the light emitting layer 2. In other words, the transparent conductive film 19 is disposed on the second cladding layer 6, so that the transparent conductive film 19 ohmically contacts with the second cladding layer 6. The transparent conductive film 19 allows the current to be uniformly applied to the entire region of the light emitting layer 2. The transparent conductive film 19 allows light as emitted from the light emitting layer 2 to be propagated through the transparent conductive film 19 and emitted from the semiconductor light emitting device.

In some cases, the transparent conductive film 19 may be realized by an indium tin oxide film (ITO film) having a thickness of approximately 100 nm. In other cases, the transparent conductive film 19 may be realized by another metal film that contains any one or mixture of nickel (Ni), platinum (Pt), palladium (Pd), rhodium (Ro), ruthenium (Ru), osmium (Os), iridium (Ir), and gold (Au).

The Schottky metal layer 18 performs as the Schottky electrode. The Schottky metal layer 18 is disposed on the bottom of the combined hole. The insulating layer 17 has a center opening 17a which is positioned over the top surface of the second region 24 of the conductive substrate 1. In the center opening 19a, the Schottky metal layer 18 contacts with the top surface of the second region 24 of the conductive substrate 1. Namely, in the center opening 19a, the Schottky metal layer 18 has Schottky junction with the second region 24 of the conductive substrate 1. In some cases, the Schottky metal layer 18 may be made of one of titanium (Ti), platinum (Pt), chromium (Cr), aluminum (Al), samarium (Sm), platinum silicide (PtSi), and palladium silicide (Pa₂Si). The combination of the Schottky metal layer 18 and the second region 24 of the conductive substrate 1 constitutes the Schottky barrier diode that performs as the protective device.

The bonding pad 20 performs as the second part of the first electrode 3. The bonding pad 20 as the second part of the first electrode 3 is positioned in plan view inside the transparent conductive film 19 as the first part of the first electrode 3. The bonding pad 20 is smaller in plan area than the light emitting layer 2. The bonding pad 20 may be made of a metal that allows a bonding wire 26 to be bonded to the bonding pad 20. The bonding wire 26 may be made of aluminum (Al) or gold (Au). The bonding pad 20 contacts with the Schottky metal layer 18. The bonding pad 20 also contacts with the transparent conductive film 19. Namely, the bonding pad 20 is electrically connected between the transparent conductive film 19 and the Schottky metal layer 18. A passivation film 27 is provided which covers the top surface and outside sloped wall of the stack of the transparent conductive film 19 and the light emitting layer 2. The passivation film 27 has an opening 27a in which the bonding pad 20 contacts with the transparent conductive film 19. In the combined hole, the bonding pad 20 contacts with the Schottky metal layer 18.

In plan view, the bonding pad 20 does overlap the light emitting layer 2 partially but not entirely. Namely, in plan view, the bonding pad 20 does not overlap at least partially the light emitting layer 2. Further, in plan view, the bonding pad 20 does at least partially overlap the protective device. Further, the bonding pad 20 provides an electrical connection between the transparent conductive film 19 as the first part of the first electrode 3 and the Schottky metal layer 18 as the Schottky electrode.

As shown in FIG. 15, the bonding pad 20 may extend not only over but outside the protective device. Namely, the bonding pad 20 may extend over the protective device and an adjacent portion of the light emitting layer 2, the adjacent portion being adjacent to the center hole 16 of the light emitting layer 2. The sloped side wall of the combined hole is covered by the insulating film 17. In the combined hole, the bonding pad 20 is separated by the insulating film 17 from the light emitting layer 2. The bonding pad 20 has a sufficient area for allowing the bonding wire 26 to be bonded to the bonding pad 20. The bonding pad 20 has the top which is higher in level than the passivation film 27 so as to make it easy to bond the bonding wire 26 to the bonding pad 20.

The bonding pad 20 has a thickness which is sufficiently thick for allowing the bonding wire 26 to be bonded to the bonding pad 20. Typically, the thickness of the bonding pad 20 may be, but is not limited to, in the range of 100 nm to 100 μm. In other words, the bonding pad 20 may be so thick as to prevent light from transmitting through it. Further, the combination of the bonding pad 20 with the bonding wire 26 is so thick as to prevent light from transmitting through it. The insulating film 17 is provided to insulate between the bonding pad 20 and the light emitting layer 2. In some cases, the insulating film 17 and the passivation film 27 may be formed in the same processes.

As shown in FIG. 15, the second region 24 of the conductive substrate 1 is covered by the bonding pad 20. The boundary between the first and second regions 8 and 24 of the conductive substrate 1 is positioned in plan view inside the edge of the bonding pad 20. It is possible as a modification, however, that the boundary between the first and second regions 8 and 24 of the conductive substrate 1 is positioned in plan view outside the edge of the bonding pad 20. In this modified case, the protective device would perform the same function as that shown in FIG. 15.

The second electrode 4 may be disposed entirely on the second main face 1b of the conductive substrate 1. Namely, the second electrode 4 contacts with both the first and second regions 8 and 24 of the conductive substrate 1. The second electrode 4 may be made of a metal. The second electrode 4 may ohmically contacts with both the first and second regions 8 and 24 of the conductive substrate 1.

In other cases, it is possible as a modification that the second electrode 4, as represented by a broken line in FIG. 15, is disposed on the conductive reflecting layer 11, instead of disposing it on the second main face 1b of the substrate 1. The second electrode 4 may be disposed at any position as long as the second electrode 4 is eclectically connected to the conductive substrate 1 but isolated from the first electrode 3.

The bonding pad 20 of the first electrode 3 may provide external connection to any external element or device through the bonding wire 26. The bonding pad 20 may also provide electrical interconnection between the light emitting device and the protective device. The bonding pad 20 interconnects the Schottky metal layer 18 as the Schottky electrode of the Schottky barrier diode and the transparent conductive film 19 as the electrode of the light emitting device. The second electrode 4 performs as a common electrode for both the Schottky barrier diode and the light emitting device.

FIG. 16 is a circuit diagram illustrating an equivalent circuit of the composite semiconductor device of FIG. 15. The composite semiconductor device can be regarded as including the first and second electrodes 3 and 4 as well as a light emitting diode 61 and a Schottky barrier diode 62. The light emitting diode 61 and the Schottky barrier diode 62 have anti-parallel connections between the first and second electrodes 3 and 4. The light emitting diode 61 performs as the light emitting device. The Schottky barrier diode 62 performs as the protective device.

The Schottky barrier diode 62 becomes conductive upon application of a reverse over-voltage to the light emitting diode 61. A typical example of the reverse over-voltage is a serge voltage. The light emitting diode 61 receives the voltage that is limited by the forward voltage of the Schottky barrier diode 62. The Schottky barrier diode 62 protects the light emitting diode 61 from the reverse over-voltage such as a serge voltage.

The Schottky barrier diode 62 has a starting voltage in forward direction that makes the Schottky barrier diode 62 conductive. The forward voltage is set lower than the maximum reverse voltage of the light emitting diode 61. The starting voltage in forward direction of the Schottky barrier diode 62 is set lower than a voltage that may break the light emitting diode 61. Preferably, the starting voltage in forward direction of the Schottky barrier diode 62 may be higher than the reverse-biased voltage that is applied to the light emitting diode 61 in normal operation mode and lower than the voltage that may break the light emitting diode 61.

As described above with reference to FIG. 15, the conductive substrate 1 has a first main face 1a and cavities 11a. The cavities 11a are adjacent to the first main face 1a and also to the side walls 1c of the conductive substrate 1. The cavities 11a are filled with the conductive reflecting layers 11. In other words, the conductive reflecting layers 11 are present in the cavities 11a. The cavity 11a extends under and outside the outside portion of the stacked structure of the buffer layer 12 and the light emitting layer 2. The conductive reflecting layer 11 in the cavity 11a also extend under and outside the outside portion of the stacked structure of the buffer layer 12 and the light emitting layer 2. The conductive reflecting layer 11 has the outside edge that is positioned in plan view outside the outside edge of the light emitting layer 2.

It is possible as a modification that the cavity 11a extends under the outside portion of the stacked structure of the buffer layer 12 and the light emitting layer 2. Thus, the conductive reflecting layer 11 in the cavity 11a also extend under the outside portion of the stacked structure of the buffer layer 12 and the light emitting layer 2. Namely, it is possible as a modification that the conductive reflecting layer 11 has the outside edge that is positioned in plan view inside the outside edge of the light emitting layer 2 or is aligned to the outside edge of the light emitting layer 2.

The conductive reflecting layer 11 has an inside portion which contacts with the bottom surface of the outside portion of the stacked structure of the buffer layer 12 and the light emitting layer 2. In some cases, the conductive reflecting layer 11 may have a smooth interface with the outside portion of the stacked structure of the buffer layer 12 and the light emitting layer 2. In other cases, the conductive reflecting layer 11 may have an irregular interface with the outside portion of the stacked structure of the buffer layer 12 and the light emitting layer 2.

It is also possible as a modification that the light emitting layer 2 contacts with the first main face 1a and the inside portion of the conductive reflecting layer 11, in the absence of the buffer layer 12. In some cases, the conductive reflecting layer 11 may have a smooth interface with the outside portion of the light emitting layer 2. In other cases, the conductive reflecting layer 11 may have an irregular interface with the outside portion of the light emitting layer 2. The irregular interface may be as described with reference to FIGS. 7, 9 and 10.

It is also possible as a further modification that the conductive reflecting layer 11 is film-shaped as described with reference to FIG. 12. The film-shaped conductive reflecting layer 11 contacts with the outside portion of the stacked structure of the buffer layer 12 and the light emitting layer 2. The film-shaped conductive reflecting layer 11 has the outside edge that is positioned in plan view outside the outside edge of the light emitting layer 2 as described with reference to FIG. 12. The most of the cavity wall of the cavity 11a is separated from the film-shaped conductive reflecting layer 11. Namely, the cavity 11a is partially filled with the film-shaped conductive reflecting layer 11.

It is also possible as a still further modification that the conductive reflecting layer 11 is film-shaped as described with reference to FIG. 12 and the buffer layer is absent. The film-shaped conductive reflecting layer 11 contacts with the outside portion of the light emitting layer 2. The most of the cavity wall of the cavity 11a is separated from the film-shaped conductive reflecting layer 11. Namely, the cavity 11a is partially filled with the film-shaped conductive reflecting layer 11.

The second region 24 of the conductive substrate 1 is present for the protective device. The second region 24 of the conductive substrate 1 is positioned under the bonding pad 20. This may avoid the reduction of the light-emitting area of the light emitting device. This may permit the size reduction of the composite semiconductor device. Further, the conductive reflecting layer 11 has the outside portion that is positioned in plan view outside the light emitting layer 2.

The light emitting layer 2 emits the beam of light, a part of which travels toward the outside portions of the conductive reflecting layers 11. The partial beam of light is then reflected by the upper surface of the outside portion of the conductive reflecting layer 11. The reflected beam of light travels upwardly, thereby improving the efficiency of the emission of light.

Each of the bonding pad 20 and the second electrode 4 provides interconnections between the light emitting diode 61 and the Schottky barrier diode 62 and also permit an external connection to any external element or device. This configuration can simplify the structure of the composite semiconductor device, thereby reducing the size and the manufacturing cost of the composite semiconductor device. The second region 24 for forming the protective device is provided in the conductive substrate 1. This configuration reduces the manufacturing cost of the Schottky barrier diode as the protective device.

If the light emitting layer 2 has a high horizontal resistance, the presence of the transparent conductive film 19 causes the majority of current to flow through the outside portion of the first region 8 of the conductive substrate 1. In this case, the conductive reflecting layers 11 may have a current path of the majority of current. The reduction in the resistance of the current path of the conductive reflecting layers 11 causes the majority of current to flow through the current path of the conductive reflecting layers 11. Namely, the reduction in the resistance of the current path of the conductive reflecting layers 11 causes the majority of current to flow through the outside portion of the first region 8 of the conductive substrate 1. The majority of current being injected into the outside portion of the light emitting layer 2 causes the outside portion of the light emitting layer 2 to emit strong beam of light, thereby improving the light emitting efficiency. Namely, the composite semiconductor device can be regarded to have a function of current diffusion to the outside portion.

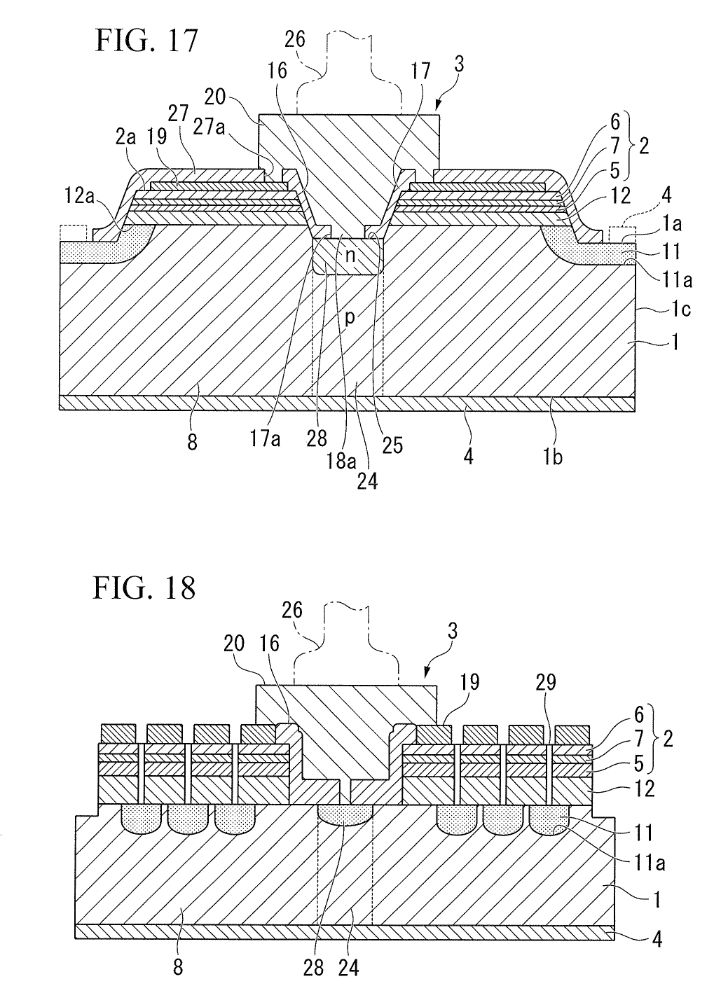

FIG. 17 is a fragmentary cross sectional elevation view illustrating a first modified composite semiconductor device in accordance with a first modification of the fourth embodiment of the present invention. The first modified composite semiconductor device of FIG. 17 is different from the composite semiconductor device of FIG. 15 in view that the Schottky metal layer 18 is absent, and an n-type semiconductor region 28 is present. The n-type semiconductor region 28 is selectively provided in the second region 24 of p-type of the conductive substrate 1. The n-type semiconductor region 28 is adjacent to the first main face 1a of the conductive substrate 1. The n-type semiconductor region 28 has a p-n junction with the second region 24 of p-type of the conductive substrate 1. The bonding pad 20 contacts with the n-type semiconductor region 28. The second electrode 4 contacts with the second region 24 of p-type of the conductive substrate 1. The first modified composite semiconductor device of FIG. 17 can be regarded as including the p-n junction diode in the conductive substrate 1. The p-n junction diode performs as a protective diode. Namely, the protective diode is realized by the p-n junction between the n-type semiconductor region 28 and the second region 24 of p-type of the conductive substrate 1. The n-type semiconductor region 28 is islanded in the second region 24 of p-type of the conductive substrate 1. The n-type semiconductor region 28 is adjacent to the first main face 1a of the conductive substrate 1. The n-type semiconductor region 28 has a face which contacts with the bonding pad 20.

The n-type semiconductor region 28 may be formed by a selective ion implantation, wherein an n-type impurity is implanted and diffused into the conductive substrate 1 of p-type. The n-type semiconductor region 28 has a p-n junction with the conductive substrate 1 of p-type. Namely, the n-type semiconductor region 28 has a top surface which faces to the center recess 25. The n-type semiconductor region 28 may have an ohmic contact with the bonding pad 20. The n-type semiconductor region 28 has the outside edge that is positioned in plan view inside the outside edge of the bonding pad 20. The first modified composite semiconductor device of FIG. 17 can provide the same advantages as the composite semiconductor device of FIG. 15.

FIG. 18 is a fragmentary cross sectional elevation view illustrating a second modified composite semiconductor device in accordance with a second modification of the fourth embodiment of the present invention. The second modified composite semiconductor device of FIG. 18 is different from the composite semiconductor device of FIG. 15. The second modified composite semiconductor device of FIG. 18 has a two-dimensional periodical array of the light emitting devices that are described above with reference to FIGS. 15 and 17. The two-dimensional periodical array is well illustrated in FIG. 18. Namely, the second modified composite semiconductor device of FIG. 18 includes penetrating holes, insulating layers 29, cavities 11a and conductive reflecting layers 11. The penetrating holes are realized by grooves that penetrate through the stacked structure of the light emitting layer 2 and the buffer layer 12. The stacked structure of the light emitting layer 2 and the buffer layer 12 has the two-dimensional periodical array of the penetrating holes.

The conductive substrate 1 also has the two-dimensional periodical array of the cavities 11a. The cavities 11a are positioned under the penetrating holes and these adjacent portions of the stacked structure which are adjacent to the penetrating holes. The conductive substrate 1 also has the two-dimensional periodical array of the conductive reflecting layers 11 that fill up the cavities 11a. The conductive reflecting layers 11 are positioned under the penetrating holes and these adjacent portions of the stacked structure which are adjacent to the penetrating holes. The conductive reflecting layers 11 contact with the adjacent portions of the stacked structure which are adjacent to the penetrating holes. Each of the penetrating holes is covered by an insulating film 29, thereby forming a closed hollow which is defined by the cavity wall and the insulating film 29.

An n-type semiconductor region 28 is selectively provided in the second region 24 of p-type of the conductive substrate 1. The n-type semiconductor region 28 is adjacent to the first main face 1a of the conductive substrate 1. The n-type semiconductor region 28 has a p-n junction with the second region 24 of p-type of the conductive substrate 1. The second modified composite semiconductor device of FIG. 18 can be regarded as including the p-n junction diode in the conductive substrate 1. The p-n junction diode performs as a protective diode.

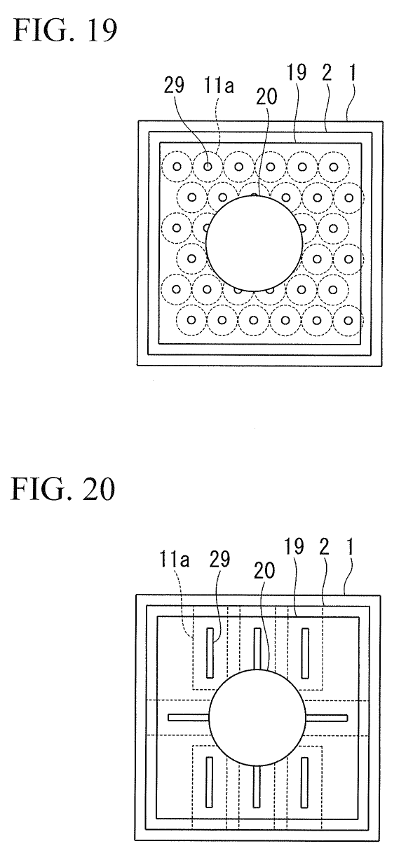

FIG. 19 is a plan view illustrating a first example of the two-dimensional periodical array structure of the second modified composite semiconductor device of FIG. 18. The light emitting layer 2 surrounds the bonding pad 20. The two-dimensional periodical array structure is present outside the bonding pad 20 and inside the outside edge of the light emitting layer 2. The two-dimensional periodical array structure as described above includes plural sets of the penetrating holes, the insulating films 29, the cavities 11a and the conductive reflecting layers 11. In some cases, as shown in FIG. 19, each of the penetrating holes, the insulating films 29, the cavities 11a and the conductive reflecting layers 11 may have a circular shape in plan view, for example.

FIG. 20 is a plan view illustrating a second example of the two-dimensional periodical array structure of the second modified composite semiconductor device of FIG. 18. The light emitting layer 2 surrounds the bonding pad 20. The two-dimensional periodical array structure is present outside the bonding pad 20 and inside the outside edge of the light emitting layer 2. The two-dimensional periodical array structure as described above includes plural sets of the penetrating holes, the insulating films 29, the cavities 11a and the conductive reflecting layers 11. In some cases, as shown in FIG. 20, each of the penetrating holes, the insulating films 29, the cavities 11a and the conductive reflecting layers 11 may have a rectangular shape or a line-shape in plan view, for example.

The first and second modified complex semiconductor devices of FIGS. 17-20 may be further modified as follows. The conductive reflecting layer 11 has a portion which contacts with the bottom surface of the penetrating-hole-adjacent portion of the stacked structure of the buffer layer 12 and the light emitting layer 2. In some cases, the conductive reflecting layer 11 may have a smooth interface with the penetrating-hole-adjacent portion of the stacked structure of the buffer layer 12 and the light emitting layer 2. In other cases, the conductive reflecting layer 11 may have an irregular interface with the adjacent portion of the stacked structure of the buffer layer 12 and the light emitting layer 2.

It is also possible as a further modification that the light emitting layer 2 contacts with the first main face 1a and the inside portion of the conductive reflecting layer 11, in the absence of the buffer layer 12. In some cases, the conductive reflecting layer 11 may have a smooth interface with the penetrating-hole-adjacent portion of the light emitting layer 2. In other cases, the conductive reflecting layer 11 may have an irregular interface with the outside portion of the light emitting layer 2. The irregular interface may be as described with reference to FIGS. 7, 9 and 10.

It is also possible as a further modification that the conductive reflecting layer 11 is film-shaped as described with reference to FIG. 12. The film-shaped conductive reflecting layer 11 contacts with the outside portion of the stacked structure of the buffer layer 12 and the light emitting layer 2. The most of the cavity wall of the cavity 11a is separated from the film-shaped conductive reflecting layer 11. Namely, the cavity 11a is partially filled with the film-shaped conductive reflecting layer 11.

It is also possible as a still further modification that the conductive reflecting layer 11 is film-shaped as described with reference to FIG. 12 and the buffer layer is absent. The film-shaped conductive reflecting layer 11 contacts with the outside portion of the light emitting layer 2. The most of the cavity wall of the cavity 11a is separated from the film-shaped conductive reflecting layer 11. Namely, the cavity 11a is partially filled with the film-shaped conductive reflecting layer 11.

It is also possible as yet a further modification that the Schottky metal layer is provided instead of the n-type semiconductor region 28.

While preferred embodiments of the invention have been described and illustrated above, it should be understood that these are exemplary of the invention and are not to be considered as limiting. Additions, omissions, substitutions, and other modifications can be made without departing from the spirit or scope of the present invention. Accordingly, the invention is not to be considered as being limited by the foregoing description, and is only limited by the scope of the appended claims.

What is claimed is:

1. A semiconductor light emitting device comprising:
a substrate having a main face and a cavity that is adjacent to the main face;
a light emitting layer extending over the main face and the cavity, the light emitting layer having a first portion that faces to the cavity, the light emitting layer having a light emitting function; and
a reflecting layer filling the cavity, the reflecting layer being higher in light-reflectivity than the substrate, the reflecting layer contacting with the first portion of the light emitting layer, and the reflecting layer having the edge that is in plan view aligned to or positioned inside the edge of the light emitting layer.

2. The semiconductor light emitting device according to claim 1, wherein the reflecting layer comprises:
a first reflecting layer; and
a second reflecting layer being in the first reflecting layer, the second reflecting layer being different in refractive index from the first reflecting layer.

3. A semiconductor light emitting device comprising:
a substrate having a main face and a cavity that is adjacent to the main face;
a light emitting layer having first and second portions, the first portion contacting with the main face, the second portion facing to the cavity, the light emitting layer having a light emitting function; and
a reflecting layer being on the second portion, the reflecting layer being higher in light-reflectivity than the substrate, the reflecting layer having an irregular interface with the first portion of the light emitting layer.

4. The semiconductor light emitting device according to claim 3, wherein the reflecting layer has at least a portion of the edge, the portion being in plan view positioned outside the edge of the light emitting layer.

5. A semiconductor light emitting device comprising:
a substrate having a main face and a cavity that is adjacent to the main face;
a light emitting layer extending over the main face and the cavity, the light emitting layer having a first portion that faces to the cavity, the light emitting layer having a light emitting function; and
a reflecting layer being in the cavity, the reflecting layer contacting with the first portion, the reflecting layer being higher in light-reflectivity than the substrate,
wherein at least a part of the wall of the cavity is separated from the reflecting layer.

6. The semiconductor light emitting device according to claim 5, wherein the reflecting layer has at least a portion of the edge, the portion being in plan view positioned outside the edge of the light emitting layer.

7. The semiconductor light emitting device according to claim 5, wherein the reflecting layer comprises:
a first reflecting layer; and
a second reflecting layer being in the first reflecting layer, the second reflecting layer being different in refractive index from the first reflecting layer.

8. A composite semiconductor device comprising:
a substrate having a main face and a cavity that is adjacent to the main face;
a light emitting layer extending over the main face and the cavity, the light emitting layer having a first portion that faces to the cavity, the light emitting layer having a light emitting function;
a reflecting layer filling the cavity, the reflecting layer being higher in light-reflectivity than the substrate, the reflecting layer contacting with the first portion of the light emitting layer;
a first electrode having first and second parts, the first part being on the light emitting layer, the second part being connected to the first part, the second part performing as a pad electrode;
a second electrode being on an opposing face of the substrate to the main face; and
a protective device placed between the second part and the opposing face, the protective device being eclectically connected to the first and second electrodes,
wherein the reflecting layer has at least a side portion that is positioned in plan view outside the edge of the light emitting layer.

9. A method of forming a semiconductor light emitting device, the method comprising:
forming a light emitting layer on a main face of a substrate, the light emitting layer having a light emitting function;
forming at least one through-hole in the compound semiconductor epitaxial layer;
forming at least one cavity in the substrate, the at least one cavity being adjacent to the main face, the at least one cavity being present under the at least one through-hole and a first portion of the light emitting layer, the first portion having a first face that faces toward the at least one cavity;
forming at least one first reflecting layer that fills the at least one cavity, the first reflecting layer being higher in light-reflectivity than the substrate; and
removing side edges of the substrate and the at least one first reflecting layer.

10. A method of forming a semiconductor light emitting device, the method comprising:
forming a light emitting layer on a main face of a substrate, the light emitting layer having a light emitting function;
forming at least one through-hole in the compound semiconductor epitaxial layer;
forming at least one cavity in the substrate, the at least one cavity being adjacent to the main face, the at least one cavity being present under the at least one through-hole and a first portion of the light emitting layer, the first portion having a first face that faces toward the at least one cavity;
making the first face into an irregular face; and
depositing at least one first reflecting layer on the irregular face, the first reflecting layer being higher in light-reflectivity than the substrate.

11. A method of forming a semiconductor light emitting device, the method comprising:
forming a light emitting layer on a main face of a substrate, the light emitting layer having a light emitting function;
forming at least one through-hole in the compound semiconductor epitaxial layer;
forming at least one cavity in the substrate, the at least one cavity being adjacent to the main face, the at least one cavity being present under the at least one through-hole and a first portion of the light emitting layer, the first portion having a first face that faces toward the at least one cavity; and
depositing at least one first reflecting layer on the first face, the first reflecting layer being higher in light-reflectivity than the substrate.

12. A semiconductor device comprising:
a substrate having a main face, the substrate having at least one cavity that is adjacent to the main face;
a compound semiconductor epitaxial layer having first and second faces adjacent to each other, the first face contacting with the main face, the second face facing toward the at least one cavity, the compound semiconductor epitaxial layer comprising at least one light emitting layer that emits light; and
a first reflecting layer being in the at least one cavity, the first reflecting layer contacting with the second face, the first reflecting layer being higher in light-reflectivity than the substrate.

13. The semiconductor device according to claim 12, wherein the first reflecting layer at least partially contacts with the wall of the at least one cavity.

14. The semiconductor device according to claim 12, wherein the first reflecting layer has an irregular interface with the second face.

15. The semiconductor device according to claim 12, further comprising:
a second reflecting layer that contacts with the first reflecting layer, the second reflecting layer being separated by the first reflecting layer from the second face, and the second reflecting layer being different in refractive index from the first reflecting layer.

16. The semiconductor device according to claim 12, further comprising:
a first electrode having first and second parts, the first part contacting with the compound semiconductor epitaxial layer, and the second part contacting with the first part;
a second electrode that contacts with the substrate; and
a protective device being electrically connected to the second part and the second electrode.

17. The semiconductor device according to claim 12, wherein the reflecting layer has the edge, at least a part of which is positioned in plan view outside the edge of the compound semiconductor epitaxial layer.

18. The semiconductor device according to claim 12, wherein the compound semiconductor epitaxial layer further includes a compound semiconductor buffer layer contacting with the main face and the reflecting layer.

19. A method of forming a semiconductor device, the method comprising:
forming a compound semiconductor epitaxial layer on a main face of a substrate, the compound semiconductor epitaxial layer including at least one light emitting layer that emits light;
forming at least one through-hole in the compound semiconductor epitaxial layer, the at least one-through hole being adjacent to a first portion of the compound semiconductor epitaxial layer;
forming at least one cavity in the substrate, the at least one cavity being adjacent to the main face, the at least one cavity being present under the first portion and the at least one through-hole, the first portion having a first face that faces toward the at least one cavity; and
forming at least one first reflecting layer in the at least one cavity, the at least one first reflecting layer contacting with the first face, the first reflecting layer being higher in light-reflectivity than the substrate.

20. The method according to claim 19, further comprising:
making the first face into an irregular face before forming at least one first reflecting layer so that the at least one first reflecting layer contacts with the irregular face.

21. The method according to claim 19, wherein forming the at least one first reflecting layer comprises completely filling the at least one cavity with the at least one first reflecting layer.

22. The method according to claim 19, wherein forming the at least one first reflecting layer comprises depositing the at least one first reflecting layer on the first face so that the at least one first reflecting layer is film-shaped and partially fills the at least one cavity.

23. The method according to claim 19, wherein forming the at least one first reflecting layer comprises partially filling the at least one first reflecting layer in the at least one cavity so that the at least one first reflecting layer has an additional cavity, and
the method further comprises:
forming a second reflecting layer in the additional cavity, the second reflecting layer being separated by the at least one first reflecting layer from the second face, and the second reflecting layer being different in refractive index from the at least one first reflecting layer.
